(19) United States
(12) Patent Application Publication
(10) Pub. No.: US 2026/0101211 A1
(43) Pub. Date: Apr. 9, 2026

(54) SYSTEMS AND METHODS FOR RADIO-FREQUENCY ANOMALY DETECTION

(71) Applicant: Distributed Spectrum Inc., New York, NY (US)

(72) Inventors: Isaac Struhl, New York, NY (US); Alexander Wulff, New York, NY (US); Benjamin Harpe, New York, NY (US); Kalman Chapman, New York, NY (US); Samuel Wolfson, Millwood, NY (US); Eric Fernandez, Jersey City, NJ (US)

(73) Assignee: Distributed Spectrum Inc., New York, NY (US)

(21) Appl. No.: 19/348,638

(22) Filed: Oct. 2, 2025

Related U.S. Application Data
(60) Provisional application No. 63/702,991, filed on Oct. 3, 2024.

(51) Int. Cl. H04W 24/08; H03M 13/29; H04L 41/16

(52) U.S. Cl. CPC H04W 24/08; H03M 13/29; H04L 41/16

(57) ABSTRACT

Aspects of the present disclosure provide improved techniques for detecting the presence of RF anomalies and providing for enhanced user control of RF anomaly detection and related actions. Some aspects relate to detecting an RF anomaly by determining, based on a multidimensional encoding of characteristics of an RF signal, that the RF signal is anomalous compared to a baseline of multidimensional encodings of characteristics of RF radiation received in the operating environment. Some aspects relate to controlling RF anomaly detection by initiating an action in response to selection of an option displayed to a user in a graphical user interface in along with an indication of an RF signal determined to be anomalous compared to a baseline. Some aspects relate to identifying a subset of RF data and determining a presence of an RF anomaly corresponding to the subset by comparing a representation of RF radiation to a baseline.

### RELATED APPLICATIONS

This application claims the benefit under 35 U.S.C. § 119(e) of U.S. Provisional Application Ser. No. 63/702,991, filed Oct. 3, 2025, under Attorney Docket No.: D0882.70005US00, and entitled “SYSTEMS AND METHODS FOR RADIO-FREQUENCY ANOMALY DETECTION,” the contents of which are herein incorporated by reference in their entirety.

### BACKGROUND

Radio frequency (RF) systems may include one or more transmitters and/or receivers and may be deployed in indoor and/or outdoor environments, such as for short and long range communication and/or radar applications. Such RF systems are susceptible to RF interference from other transmitters in the environment that broadcast RF signals in the operating frequency range of the RF system.

Some existing systems detect the presence of RF signals using one or more RF receivers. Some existing systems process RF signals to determine the location of the source of the RF signals. For example, in a time difference of arrival (TDOA) system, multiple RF receivers may be positioned in different locations to receive and process the same RF signal, and time differences between the arrival of the RF signal at the different RF receivers may be used to determine the location of the source of the RF signal relative to the RF receivers.

### BRIEF SUMMARY OF THE DISCLOSURE

Aspects of the present disclosure provide improved techniques for detecting the presence of RF anomalies and providing for enhanced user control of RF anomaly detection and related actions. Some aspects relate to detecting an RF anomaly by determining, based on a multidimensional encoding of characteristics of an RF signal, that the RF signal is anomalous compared to a baseline of multidimensional encodings of characteristics of RF radiation received in the operating environment. Some aspects relate to controlling RF anomaly detection by initiating an action in response to selection of an option displayed to a user in a graphical user interface in along with an indication of an RF signal determined to be anomalous compared to a baseline. Some aspects relate to identifying a subset of RF data and determining a presence of an RF anomaly corresponding to the subset by comparing a representation of RF radiation to a baseline.

The inventors have recognized that it is advantageous for an RF sensing system to detect RF anomaly events occurring in an operating environment. RF anomaly events may be determined with respect to a baseline of RF events that have been observed and/or are expected to occur in the operating environment (e.g., within a particular time, frequency, and bandwidth window). However, RF anomaly detection can be resource intensive, especially when detection is performed over a large range of frequencies and/or with high resolution. For instance, performing RF anomaly detection over a full range of frequencies of interest using raw digital samples of RF radiation may result in a large amount of RF data to process, which requires significant computing resources in order to obtain an accurate determination of an RF anomaly. Moreover, attempting to integrate user control over the RF anomaly detection process would further increase the amount of computing resources needed to provide flexibility in the detection process.

Accordingly, the inventors have developed several techniques to make RF anomaly detection more computationally efficient and easier to control without compromising accuracy. These aspects may be implemented individually or in any combination or sub-combination, for example, in a distributed system including an RF sensor, a computer system configured to process encodings of RF signals received by the RF sensor to provide indications of received RF signals for display to a user in a graphical user interface.

Some aspects relate to detecting an RF anomaly by determining, based on a multidimensional encoding of characteristics of an RF signal, that the RF signal is anomalous compared to a baseline of multidimensional encodings of characteristics of RF radiation received in the operating environment. The inventors have recognized that multidimensional encodings of characteristics of RF signals provide a useful and potentially compact data structure for RF anomaly detection, which anomaly detection may be implemented using limited computing resources and/or as part of a distributed computing architecture using limited network bandwidth. For example, the multidimensional encoding may consume less memory than digital samples of received RF radiation that indicate (e.g., include) the RF signal.

In some embodiments, a multidimensional encoding of characteristics of an RF signal may represent the RF signal in a multidimensional space that allows for easy comparison of several characteristics of the RF signal at once to determine whether the RF signal is anomalous compared to a baseline, as the baseline may also be represented in the multidimensional space. For example, each characteristic may correspond to a dimension in the multidimensional space. According to various embodiments, characteristics may include classical signal characteristics (e.g., human intelligible) such as power level, frequency, and bandwidth, and/or characteristics may include machine readable features (e.g., encoded using a trained model) that emphasize intangible aspects of RF radiation that are useful to quantify many different types of similarities and differences between RF signals.

Some aspects relate to identifying a subset of RF data and determining a presence of an RF anomaly corresponding to the subset by comparing a representation of RF radiation to a baseline. The inventors have recognized that identifying a subset of RF data in which to perform RF anomaly detection provides a more focused use of computing resources than performing the same anomaly detection process over the full spectrum and/or reception window of RF data. For example, the RF data may correspond to a full scan of RF radiation performed by an RF sensor, whereas the subset of the RF data may include particular frequencies and/or times that are identified to be of interest for RF anomaly detection. Since the subset of the RF data may correspond to a smaller set of RF radiation than the full set of RF data, high resolution detection of RF anomalies may be performed using limited computing resources.

In some embodiments, RF data of a first frequency range may be obtained, over which an RF sensor scans for RF radiation. For example, the RF sensor may be configured (e.g., based on instructions) to scan a full frequency range and/or time window and provide RF data (e.g., digital samples and/or a time-frequency representation such as a spectrogram). In some embodiments, the subset of RF data in which to detect RF anomalies may be identified within the RF data. For example, the subset of the RF data may be identified based on characteristics such as exceeding a predetermined power level and/or having a predetermined power level over a predetermined bandwidth. As another example, the subset of the RF data may be identified based on comparison to a limited baseline, such as a baseline of RF signals within a particular frequency range within the first frequency range and/or in a particular time window within a sub-period of the RF data. For instance, identification of the subset of the RF data may use less computing power per unit of frequency or time than determining the presence of an RF anomaly within the RF subset. Alternatively or additionally, identification of the subset may provide an indication for further anomaly detection that a detected RF signal is anomalous with respect to that subset (e.g., frequency and/or time period), as an alternative or in addition to being anomalous with respect to an overall baseline (e.g., for the RF data as a whole).

In some embodiments, determining the presence of the RF anomaly may be performed using data that corresponds to the identified subset of the RF data. For example, a representation of the subset of the RF data may be compared to a baseline to determine the presence of the RF anomaly in the subset. Alternatively or additionally, a representation of RF radiation data in a frequency range and/or time period of the subset of RF data may be compared to the baseline. For instance, identification of the subset may be used to perform anomaly detection in RF radiation data that is received or obtained in the same frequency range and/or time period as the subset after identification of the subset.

Some aspects relate to controlling RF anomaly detection by initiating an action in response to selection of an option displayed to a user in a graphical user interface in along with an indication of an RF signal determined to be anomalous compared to a baseline. The inventors have recognized that interactive user control over RF anomaly detection is advantageous for adaptively improving the accuracy and use of computing resources, such as to focus on RF anomalies that are of interest. As one example, a user action may include instructing an RF sensor in the system to search for and/or provide indications of the RF anomaly from previously received and/or future RF radiation. As another example, a user action may include ignoring the RF anomaly, such as by not providing a visual indication of the RF anomaly when detected again, and/or by adding the RF anomaly to the baseline such that the RF anomaly is not determined to be an RF anomaly in future anomaly detection processes.

In some embodiments, an indication of an RF signal determined to be anomalous compared to a baseline may be displayed with an option selectable by the user to initiate an action by the RF system associated with (e.g., which received) the RF signal. For example, the indication of the RF signal may include indications of characteristics such as power level, frequency, time of reception, and/or bandwidth. In the same or another example, the action may include adding the RF signal to the baseline, ignoring the RF signal (e.g., not providing future alerts as an alternative or in addition to adding the RF signal to the baseline), obtaining digital samples of the RF signal, instructing an RF sensor to provide digital samples of RF radiation associated with the RF signal, and/or communicating an alert indicating the RF signal.

It should be appreciated that aspects described herein may be implemented individually and/or in combination depending on the particular application.

### BRIEF DESCRIPTION OF THE DRAWINGS

FIG. 1 is a block diagram of an example system for RF anomaly detection, according to some embodiments.

FIG. 2 is a graph of an example multidimensional space in which RF radiation may be encoded, according to some embodiments.

FIG. 3 is a flow diagram of an example method of RF subset identification and RF anomaly detection within the identified RF subset, according to some embodiments.

FIG. 4 is a view of an example interactive graphical user interface for RF anomaly detection control, according to some embodiments.

FIG. 5 is a schematic diagram of an example system for RF anomaly detection, according to some embodiments.

FIG. 6A is a spectrogram of example RF signals received over time, according to some embodiments.

FIG. 6B is a graph of power spectral density of the example RF signals of FIG. 6A, according to some embodiments.

FIG. 7 is a view of a first example interactive graphical user interface screen indicating a detected RF anomaly, according to some embodiments.

FIG. 8 is a view of a second example interactive graphical user interface screen providing RF anomaly detection controls, according to some embodiments.

FIG. 9 is a view of a third example interactive graphical user interface screen indicating a detected RF anomaly, according to some embodiments.

FIG. 10 is a partial graph of a multidimensional space in which RF signals have been encoded and grouped in clusters of predetermined multidimensional distance, according to some embodiments.

FIG. 11 is a partial graph of a multidimensional space in which an RF baseline has been encoded and RF anomalies have been determined based on a predetermined multidimensional distance, according to some embodiments.

FIG. 12A is a first portion of a block diagram of an example trained model configured to receive RF radiation as an input and to provide a multidimensional encoding of an RF signal in the RF radiation as an output, according to some embodiments.

FIG. 12B is a second portion of a block diagram of the example trained model of FIG. 12A, according to some embodiments.

### DETAILED DESCRIPTION OF EXAMPLE EMBODIMENTS

### I. Overview of RF Anomaly Detection

As described above, the inventors have developed several techniques to make RF anomaly detection more computationally efficient and easier to control without compromising accuracy.

In some embodiments, radio frequency (RF) signal encodings (e.g., multidimensional encodings), digital samples, in-phase and quadrature (IQ) data, and/or characteristics extracted from digital samples, IQ data, and/or encodings (such as a power spectral density and/or extracted modulation characteristics) may be used by downstream (e.g., on-sensor and/or server-side) processes to detect anomalies in an operating environment. An RF “anomaly” may include: (A) at least a predetermined deviation from a predetermined operating condition of an RF signal and/or of an RF source of that RF signal, which may be observed by an RF sensor, (B) an RF signal transmitted by an RF source that has not transmitted any RF signals included in a baseline associated with the operating environment, and/or (C) an RF signal transmitted by an RF source that has transmitted an RF signal included in the baseline, but which deviates more than a predetermined amount from the RF signal(s) from that RF source which are included in the baseline. In some embodiments, deviations may include identification of a new RF source appearing in an operating environment and/or a change in operating characteristics of a recognized and/or previously identified RF source. Individual measurements of RF signals may be linked to an RF source (e.g., having a physical instance in the operating environment) by a downstream process that takes digital samples and/or an encoding of the RF signal as an input (e.g., executed by a computer system in communication with the RF sensor).

Such a change in operating characteristics of an RF source, for example, may include a change in waveform parameters (e.g. the bandwidth of an orthogonal frequency division multiplexed (OFDM) signal increasing from 5 MHz to 10 MHz and/or a chip rate of a low bandwidth (e.g., LoRa) and/or low power transmission decreasing from 8000 chips/s to 2000 chips/s), the RF source switching to transmitting an entirely new waveform at a later time after transmitting a previous waveform at an earlier time, a change in power level of the RF source, a change in center frequency of the RF source, and/or a deviation in transmission rate (e.g. an RF source that normally broadcasts with an interval of 10 ms). A complete change in waveform (e.g., from one modulation type to another, from one frequency range to another, etc.) may still be linked to the same RF source by similarities in other features (e.g., by a downstream process and a database storing other observed common parameters associated with the new waveform), such as similar relative power levels received at multiple RF sensors, similar observed location of the RF source, and/or fingerprint characteristics intrinsic to the RF source such as RF power rise time. Similarly, an RF source that substantially changes center frequency may be identified as the same RF source using the same common characteristics mentioned above, regardless of whether the waveform is maintained or changed at the different center frequency. In some embodiments, an anomalous RF signal may occupy the same time and/or frequency range as an RF signal in the baseline. For example, such an anomalous RF signal may indicate intentional interference (e.g., jamming) and/or unintentional interference (e.g., from a lost person or malfunctioning device).

RF anomaly detection techniques (e.g., executed onboard an RF sensor and/or on a computer configured to receive RF characteristic data from an RF sensor) may identify an RF anomaly by comparing new RF data (which may include RF signal encodings such as multidimensional encodings, RF characteristic data and/or IQ data) against an environmental baseline of the same data type (e.g., multidimensional encodings being compared in a common multidimensional space). This baseline may include RF radiation measurements (e.g., received RF signals and/or RF noise) over a period of time (e.g., ranging from seconds to years) conducted by one or more RF sensors (e.g., stationary and/or mobile RF sensors). This comparison may be performed against historical data collected by the same RF sensor that produced the new RF measurements for comparison, and/or against historical data from different RF sensors in the network. In some embodiments, a baseline may be constructed from a first time period of observation of the operating environment and anomaly detection may be performed in a second time period of observation that precedes and/or follows the first time period of observation by substantially any or no intervening time period, depending on the particular application and objective. In some embodiments, a baseline may be constructed over multiple geographical locations within a corresponding time period (e.g., overlapping and/or periodic).

In one embodiment, representations of RF signals (e.g., multidimensional encodings) may be compared against an environmental baseline, for example, to identify a new RF source not previously associated with an operating environment. To identify a new RF source, for example, RF anomaly detection techniques may include a comparison algorithm to determine that a given RF measurement is substantially different from any previous recordings of measurements and thus constitutes an RF anomaly. This comparison may be performed based on a single measurement, and/or based on groups of measurements that are associated with a same RF source (e.g., based on associations input by a user and/or determinations of similarity performed by a downstream process).

RF anomaly detection may be executed on a computer hosting other processing elements for the system, such as a server computer. This computer may be configured to receive RF signal encodings, IQ data, and/or RF characteristic data over a network link from one or more (e.g., deployed) RF sensors. Alternatively or additionally, anomaly detection may be executed directly on an RF sensor, which may eliminate, in part or entirely, the need for a network link. According to various embodiments, components used in the anomaly detection process may also be distributed across various computers and/or RF sensors in the network. For example, an RF sensor used for the first step of the multi-step anomaly detection process described above may be configured to execute a simpler and/or faster baselining algorithm and directly or indirectly instruct other RF sensors in the system on characteristics (e.g., frequency range and/or timing, and/or by providing an encoding such as a multidimensional encoding) for tracking a given anomaly without input from an additional processor.

In some embodiments, anomaly detection techniques may provide results for displaying in various user interfaces to users (e.g., system operators). Example user interfaces may expose control parameters for user selection, allow users to analyze identified RF anomalies (e.g., by viewing characteristics and/or the bases of anomaly designation), and/or take downstream action (e.g., alert, jam, etc.) on identified anomalies.

### II. Example Systems for RF Anomaly Detection

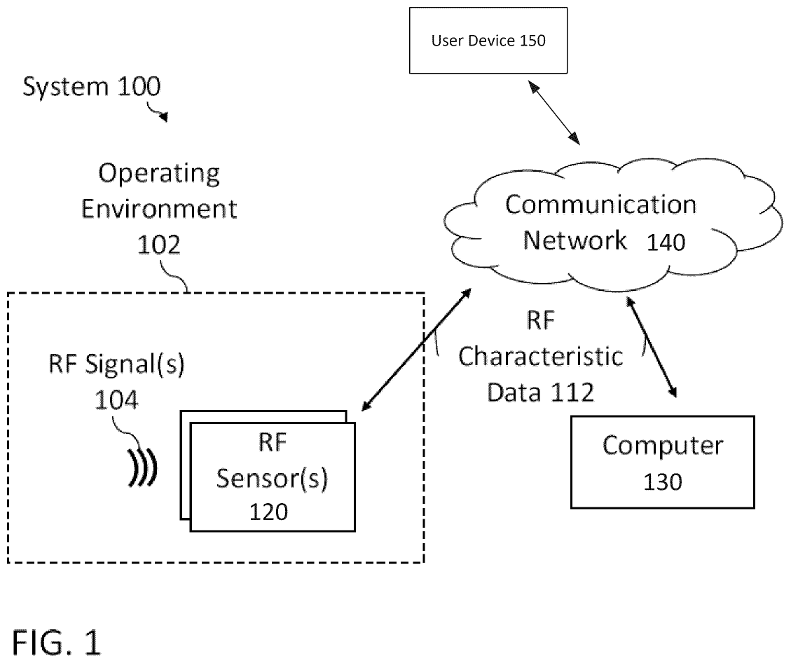

FIG. 1 is a block diagram of an example radio frequency (RF) signal processing system 100, according to some embodiments. As shown in FIG. 1, system 100 may include one or more RF sensors 120 configured to receive RF signals 104 in an operating environment 102 of the system 100 and a computer 130 communicatively coupled to the RF sensor(s) 120 via a communication network 140. Further shown in FIG. 1, system 100 may include one or more user devices 150. In some embodiments, RF sensor(s) 120 and/or computer 130 may be configured to detect the presence of received RF signals 104 among RF radiation received by RF sensor(s) 120. Alternatively or additionally, in some embodiments, RF sensor(s) 120 and/or computer 130 may be configured to determine whether the RF signal(s) 104 are anomalous, as described further herein. In some embodiments, user device 150 may be configured to provide interactive control over RF anomaly detection by a user. In some embodiments, computer 130 may be configured in a centralized configuration (e.g., as a central server and/or base station), whereas in other embodiments, computer 130 may be configured in a distributed configuration (e.g., as a distributed cloud server system).

According to various embodiments, the operating environment 102 may be indoor, outdoor, or partially indoor and partially outdoor. For instance, the operating environment 102 may be as small as a single room, or as large as a neighborhood and/or city. In one example, the operating environment 102 may be a compound spanning multiple buildings. As another example, the operating environment 102 may be a warehouse. In yet another example, the operating environment 102 may be a city and/or a neighborhood within a city, as embodiments described herein are not so limited. For example, in embodiments that may be deployed in combat areas, the operating environment 102 may include all or part of an active combat zone or battlefield. Depending on the application and/or operating environment 102, RF sensors 120 may be placed in various arrangements and at various densities. For example, in a dense environment with a high degree of signal attenuation (e.g., due to LOS obstruction and/or multipath reflections), a correspondingly dense arrangement of RF sensors 120 may be deployed.

In some embodiments, RF sensor(s) 120 may be configured to receive RF radiation in the operating environment 102 of system 100. For example, one RF sensor 120 may be positioned in the operating environment 102 and have one or more RF antennas configured to receive RF radiation. Alternatively, multiple RF sensors 120 may be positioned in the operating environment 102, such as in different respective locations. In some embodiments, the RF sensor(s) 120 may be configured to receive RF radiation having a frequency of at least 1 MHz, such as 50 MHz, 900 MHz, 2.4 gigahertz (GHz), 30 GHz, and/or higher. In some embodiments, the RF sensor(s) 120 may also include RF front-end circuitry, such as one or more filters, amplifiers, tuners, and/or ADCs configured to receive, condition, demodulate, and/or digitally sample received RF radiation for processing. In some embodiments, some or all components of the RF front-end circuitry and/or RF antenna(s) may be contained in a dedicated system-on-chip (SoC) and/or a software-defined radio (SDR). For example, the SoC and/or SDR may be configured to selectively tune to one or more operating frequencies to scan for RF signal(s) 104. In some embodiments, the SDR may have an adjustable sampling rate to suit various possible processing speeds of the RF sensor 120 (e.g., a high sampling rate for use with fast processing speed, etc.).

In some embodiments, RF sensor(s) 120 may be configured to detect the presence of one or more RF signals 104 among the RF radiation received by RF sensor(s) 120. For example, each RF sensor 120 may include a processor operatively coupled to memory and configured to receive RF radiation from the RF antenna(s) of the RF sensor 120 (e.g., via RF front-end circuitry) and provide, as an input to a trained signal detection model, RF radiation data indicating characteristics of the RF radiation. For instance, the RF radiation data may include digital samples of the RF radiation and/or a time-frequency representation (e.g., spectrogram) derived from digital samples. In this example, the trained signal detection model may be configured to detect the presence of RF signals 104 by determining which portion (e.g., time period, frequency range, and/or power level) of the RF radiation data correspond to the RF signal(s) 104.

In some embodiments, RF sensor(s) 120 may be configured to provide RF radiation data to a trained model and obtain as an output from the trained model a representation (e.g., multidimensional encoding) of an RF signal within the RF radiation data. For example, a representation may be compressed with respect to the RF radiation data while still indicating distinguishing characteristics of the RF signal, which may facilitate processing the RF signal on less data than if the RF radiation data were processed in an uncompressed state. For instance, a representation may be decoded by a downstream model for further processing, and/or a multidimensional encoding may have content in dimensions of the encoding that may be further processed directly such as to compare encodings of RF signals and/or to determine whether an encoding should be associated with a category of RF signals associated with a particular multidimensional space. In some embodiments, RF signal detection may be implicit within a trained model configured to receive RF radiation data and output an encoding of an RF signal, whereas in other embodiments, a separate RF signal detection model may be included (e.g., to receive the RF radiation data and provide an input to another model that outputs the encoding).

In some embodiments, the processor may be configured to obtain the RF radiation data from received, filtered, demodulated, and/or digitally sampled RF radiation. For example, the processor may be configured to perform a Fourier Transform on digital samples of the RF radiation and generate a time-frequency representation and/or spectrogram of the RF radiation over a plurality of discretely sampled time periods, which may be provided as the input to the trained signal detection model. Alternatively or additionally, digital samples of RF radiation may be provided directly as an input to the trained signal detection model.

In some embodiments, the processor may be configured to determine, using the output of the trained signal detection model, at least some characteristics of the RF signal(s) 104. For example, the processor may be configured to determine the operating frequency of the RF signal(s) 104, such as the center frequency and/or operating frequency band, the power level of the RF signal(s) 104 at any such frequency or frequencies, bandwidth, pulse rate, signal metric (e.g., signal-to-noise ratio (SNR)), the extent to which a received RF signal 104 is analog and/or digital, the extent to which an RF signal 104 matches another RF signal (e.g., previously received and/or having predetermined characteristics) by comparison, and/or the extent to which an RF signal 104 has a particular characteristic (e.g., modulation type, analog and/or digital).

In some embodiments, the trained signal detection model may be configured to detect the presence of multiple RF signals 104 among the RF radiation, at least some of which may be received at the same time and/or within a predetermined time interval of one another. In some embodiments, the trained signal detection model may be trained using real RF signals received by RF sensor 120 in the operating environment 102. Alternatively or additionally, the trained signal detection model may be trained with RF radiation data generated using one or more real RF signals. For example, a large amount of RF radiation data may be generated to train the signal detection model to detect a wide variety of RF signals, thereby simulating training the model with a large dataset of real RF signals while using only a small number of real RF signals. Alternatively or additionally, the trained signal detection model may be trained with RF radiation data generated using one or more simulated RF signals. For example, a simulated RF signal may be generated to have characteristics in common with real RF signals, such as various types of modulation. In some embodiments, simulated RF signals may be generated by providing a real RF signal to a model that outputs simulated RF signals based on the real RF signal. In some embodiments, a real RF signal may be sampled at different sample rates to obtain a number of simulated RF signals, and/or spectrograms and/or power spectral density information may be obtained from the RF signal and/or different samplings of the RF signal to obtain more simulated RF signals.

In some embodiments, real signals may be used to generate simulated signals, such as by resampling the real signals at a different rate, varying the power level, and/or adding or modifying the noise level and/or type. The inventors recognized that real signals may be useful for accurately training models but may require manual signal labeling, whereas simulated signals may be less accurate in some cases but may be automatically labeled as part of generating the simulated signals. In some embodiments, a combination of real and simulated signals generated using real signals may be advantageously used to train models described herein efficiently while still achieving accurate signal detection and characterization.

In some embodiments, RF sensor(s) 120 may be configured to transmit (e.g., over a wired and/or wireless connection) RF characteristic data 112 to computer 130 indicating characteristics of received RF radiation. For example, RF sensor(s) 120 may include a network interface (e.g., coupled to and/or executed by the processor) configured to connect to communication network 140 such that RF sensor(s) 120 are configured to send RF characteristic data 112 indicating characteristics of the RF signal(s) 104 to computer 130 over communication network 140. For instance, the characteristics may include an operating frequency, power level, bandwidth, pulse rate, signal metric (e.g., signal-to-noise ratio (SNR), the extent to which the RF signal is analog and/or digital, and/or the extent to which the RF signal matches another RF signal (e.g., previously received and/or having predetermined characteristics) by comparison. In some embodiments, RF characteristic data 112 may alternatively or additionally include RF signal data indicating and/or including a portion of RF radiation data (e.g., digital samples) corresponding to a received RF signal 104. Alternatively or additionally, in some embodiments, RF sensor(s) 120 may be configured to store RF characteristic data 112 locally (e.g., in memory onboard the RF sensor(s) 120) until the data is transmitted and/or offloaded at a later point.

In some embodiments, RF sensor(s) 120 may be configured to transmit RF characteristic data 112 to computer 130 each time an RF signal 104 is detected at the RF sensor(s) 120.

Alternatively, in some embodiments, RF sensor(s) 120 may be configured to transmit RF characteristic data 112 to computer 130 only when certain RF signals 104 are detected, such as having at least one of a set of predetermined characteristics, such as one or more operating frequencies, power levels, combinations thereof, characteristics derived from an RF signal using a trained model, and/or content in an encoding of an RF signal. For example, computer 130 may be configured to execute and/or may be coupled to an interface operable by a user to determine signal characteristics for RF signals to be detected and reported to computer 130 and/or to the interface. Alternatively or additionally, in some embodiments, RF sensor(s) 120 may be configured to transmit RF characteristic data 112 to computer 130 only when a new RF signal 104 is detected, such as when the detected RF signal 104 is not associated with the operating environment 102, when first the RF signal 104 is detected by the system, or when the RF signal 104 is first detected after a predetermined time period has passed (e.g., one hour, one day, etc.). In further embodiments, RF sensor(s) 120 may be configured to transmit RF characteristic data 112 to computer 130 in response to instructions from computer 130 to transmit the RF characteristic data 112, such as instructions indicating particular characteristics (e.g., encoded characteristic ranges, frequency ranges, and/or time periods of reception). Such instructions may be in response to user action, as described further herein.

Further alternatively or additionally, in some embodiments, RF sensor(s) 120 may be configured to store RF characteristic data 112 locally in memory and only transmit RF characteristic data 112 upon request by computer 130 (e.g., when queried for detection of any RF signals, and/or of an RF signal satisfying specified criteria). For instance, RF sensor(s) 120 may be configured to store RF characteristic data 112 only for a predetermined amount of time and/or until a predetermined amount of memory is used and then to overwrite the memory with newly generated RF characteristic data 112 for efficiency. Alternatively or additionally, RF sensor(s) 120 may be configured to only store RF characteristic data 112 locally in memory and/or only transmit RF characteristic data 112 for an RF signal that satisfies a constraint received from computer 130, such as including a filter on content in dimensions of a multidimensional encoding of the RF signal and/or a constraint of similarity of (e.g., multidimensional distance between) a multidimensional encoding of the RF signal and a reference multidimensional encoding of a reference RF signal that is provided by computer 130.

In some embodiments, computer 130 may be configured to associate an RF signal with other RF signals, such as from the same RF source, using the RF characteristic data 112 received from the RF sensor(s) 120. For example, RF signals may be associated using multidimensional encodings of the RF signals, based on content in dimensions of the encodings having multidimensional distances that indicate an association, and/or using a trained model to decode the encodings and/or a trained model to classify and/or regress the type and/or location of the RF source that transmitted the RF signal(s) 104. For instance, computer 130 may include a processor operatively coupled to memory and configured to execute one or more trained models and provide the RF characteristic data (e.g., RF signal data within the RF characteristic data) to the trained model(s) as an input.

In some embodiments, computer 130 may be configured to classify the type of RF source that transmitted the RF signal(s) 104 using a trained source classification model and to classify and/or regress the location of the RF source using a trained localization model. For example, the trained source classification model may be trained using RF signal data indicating characteristics of RF signals transmitted by a variety of RF source types, such as cell phones and Bluetooth and/or Wi-Fi devices. In this example, the trained source localization model may be trained using RF signal data indicating characteristics of RF signals transmitted from a variety of locations within the operating environment 102 of system 100. Alternatively or additionally, in some embodiments, the source classification and/or localization models may be trained using a large dataset of RF signal data generated based on a small number of RF signals received in the operating environment 102, which may simulate training the models based on a large number of real RF signals. Alternatively or additionally, the trained source classification and/or localization models may be trained using RF signal data generated based on one or more simulated RF signals.

In some embodiments, computer 130 may be configured to perform RF anomaly detection using representations of RF signals 104 received by RF sensors 120. For example, RF anomaly detection may distinguish between RF signals 104 in a baseline associated with the operating environment 102 and other RF signals 104 that are different enough from the baseline to not be associated with the operating environment 102. As a high-level example, phase modulated (PM) communication traffic at 10 GHz may be included in a baseline associated with the operating environment 102, and an unauthorized person could enter the operating environment 102 with a non-associated mobile communication device that transmits PM signals at 900 MHz, which is significantly different from the baseline. In this example, RF anomaly detection executed by computer 130 may be configured to determine that the PM communication traffic and the mobile communication device PM signals are different enough to result in an RF anomaly detection, allowing computer 130 and/or an operator thereof to detect the presence of the unauthorized person based on the trained model outputs described herein. Other high-level examples of RF anomalies include malfunctioning equipment, which may result in a deviation in operating condition of an otherwise similar RF signal, such as a different center frequency, bandwidth, or time window in which the RF signal is received.

In some embodiments, a baseline used for anomaly detection may include previously processed signals. Alternatively or additionally, a baseline may include a statistical model, such as a list of expected RF signals and associated probabilities, and/or an encoding space occupied by representations of such RF signals. Further alternatively or additionally, a baseline may be generated for a particular type of operating environment (e.g., airport) in which the RF sensor 120 that received the new RF signal 104 has been deployed, which may be associated (e.g., in the memory of computer 130) with a list of expected RF signals and/or a statistical model.

In some embodiments, characteristics encoded in dimensions of multidimensional encodings of RF signals may be used to distinguish between received RF signals 104 and a baseline. For example, multidimensional encodings of RF signals 104 in the baseline may occupy particular multidimensional space(s), and a multidimensional encoding of an RF signal may occupy a multidimensional space that is significantly distanced (in multidimensional distance) from the space(s) occupied by the baseline, indicating that the RF signal is significantly different from the baseline. Alternatively or additionally, a multidimensional encoding of an RF signal may have some very similar (e.g., close in multidimensional distance) characteristics (e.g., in some dimensions) while having some very different (e.g., far in multidimensional distance) characteristics (e.g., in other dimensions), which may indicate that the RF signal is a new version of an RF signal that is in the baseline, such as an RF signal having the same modulation type and/or confidence metric of being analog and/or digital while having a different center frequency. Depending on how varied the characteristics are, an RF signal that has deviated somewhat from the baseline may still be identified as within the baseline as opposed to anomalous, such as depending on a predetermined multidimensional distance around the baseline, beyond which RF signals are determined to be anomalous.

In some embodiments, communication network 140 may be a wired and/or wireless local area network (LAN), a cell phone network, a Bluetooth network, the internet, or any other such network. For example, RF sensor(s) 120 and computer 130 may be positioned in remote locations relative to one another, such as with RF sensor(s) 120 deployed in the operating environment 102. In some embodiments, RF sensors 120 described herein may be used with various types of communication links within communication network 140, such as low bandwidth communication links. In one example, an RF sensor 120 described herein may be configured to transmit messages (e.g., including RF characteristic data 112) at a data rate less than or equal to 50 kilobits per second (kbps), such as 30 kbps, 20 kbps, or less. For instance, low bandwidth communication described herein may use a Low Power Wide Area Networking (LPWAN) communication protocol, such as the LoRaWAN protocol. In some embodiments, RF sensor 120 may be configured to transmit RF characteristic data 112 in messages having as few as 100 bytes, 50 bytes, or even 10 bytes. It should also be appreciated that multiple communication links of various bandwidths may be used herein, such as one RF sensor 120 connected to computer 130 over LoRaWAN and another RF sensor 120 connected to computer 130 over 802.11ac, as embodiments described herein are not so limited.

In some embodiments, as an alternative or in addition to RF sensor 120, computer 130 may be configured to detect the presence of an RF signal among RF radiation received by an RF sensor 120, such as by inputting RF radiation data (e.g., digital samples, a spectrogram, etc.) from the RF sensor 120 to a trained signal detection model executed by computer 130 and identifying the RF signal among the RF radiation data. For example, RF sensors 120 may have low onboard processing resources and may be configured to transmit a large quantity of RF radiation data (e.g., including digital samples) over a high-bandwidth link of communication network 140. Alternatively or additionally, an RF sensor may have enough onboard processing resources to detect an RF signal, classify the RF source, and/or determine the operating condition of the RF source, facilitating transmission of a small quantity of RF characteristic data over a low-bandwidth link of communication network 140, according to the needs of the particular deployment.

While computer 130 is described herein as performing RF anomaly detection, it should be appreciated that such processing may be alternatively or additionally performed by RF sensor 120. For example, RF characteristic data 112 transmitted to computer 130 may alternatively or additionally include an indication of an RF anomaly determination and/or identification of a subset of RF data for RF anomaly detection, as embodiments described herein are not so limited. It should also be appreciated that, in some embodiments, computer 130 may be implemented onboard one or more RF sensors 120. For example, system 100 may be at least partially decentralized, such as having at least one of RF sensors 120 designated as a controlling device for at least a portion of system operation. As another example, computer 130 may be distributed using a distributed cloud computing system accessible to the RF sensor(s) 120 over the Internet.

In some embodiments, an at least partially decentralized implementation of system 100 may have an RF sensor 120 configured to selectively report (e.g., to a computer 130) RF signals satisfying a constraint (e.g., corresponding to a particular RF signal and/or based on certain features such as power level and/or operating frequency, and/or multidimensional distance between multidimensional encodings), and the RF sensor 120 may be configured to hibernate in a low power mode (e.g., performing less frequent RF signal scanning) after a predetermined amount of time (e.g., 10 minutes) has passed since detecting an RF signal satisfying the constraint. For example, an RF sensor 120 may be configured to hibernate after a predetermined amount of time has passed without detecting an RF signal that is determined to be anomalous. In this respect, for instance, an RF sensor 120 may be at least partially in control of the process flow within the system 100.

In some embodiments, RF sensor(s) 120 may be deployed in stationary locations (e.g., without moving during operation of system 100). Alternatively or additionally, in some embodiments, RF sensor(s) 120 may be positioned on (e.g., mounted on and/or carried by) one or more vehicles, such as wheeled, aerial, manned, and/or unmanned vehicles in and/or around the operating environment 102. In one example, a known location of the vehicle (e.g., determined using a GPS receiver co-located with the vehicle) and/or a known relative distance between multiple vehicles supporting respective RF sensors 120 may be used to determine the location of an RF source (e.g., by providing such information with RF characteristic data 112). For instance, RF sensors 120 onboard multiple vehicles traversing an operating environment 102 may be configured to collaboratively detect RF signals and/or classify and/or locate RF sources in the operating environment 102 so as to map the RF sources present as the vehicles traverse the operating environment 102. In another example, a known location of an RF source localized using system 100 may be used to determine the location of the vehicle (e.g., using a trained localization model). As yet another example, one or more RF sensors 120 may be worn and/or carried by persons, who may have known locations (e.g., determined using a GPS receiver co-located with the person).

In some embodiments, an RF sensor and/or device may be co-located with a vehicle and/or person when the RF sensor and/or device and the vehicle and/or person are affixed to one another, such as by wearing or mounting. It should be appreciated, however, that co-location may be possible without direct affixation or attachment. For example, an RF sensor may be considered co-located with a positioning device onboard a vehicle and/or worn by a person when a positional offset between the RF sensor and the positioning device is known and is shorter than positional offsets between objects in the area such as people, vehicles, or landmarks. In some cases, positional offsets between co-located devices may be insignificant enough to be ignored for processing purposes. For example, on a vehicle, positioning devices such as GPS and IMU units may be offset from one another by inches or feet, which may be programmed into memory and/or may be trained into layers of a model when fine-tuned with the vehicle. Similarly, devices carried by a person may be so close to one another that positional offsets between them may be ignored for purposes of RF source localization. It should be appreciated, however, that some implementations may require enough precision that co-location requires precise, known offsets.

### III. Example RF Anomaly Detection Using Multidimensional Encoding

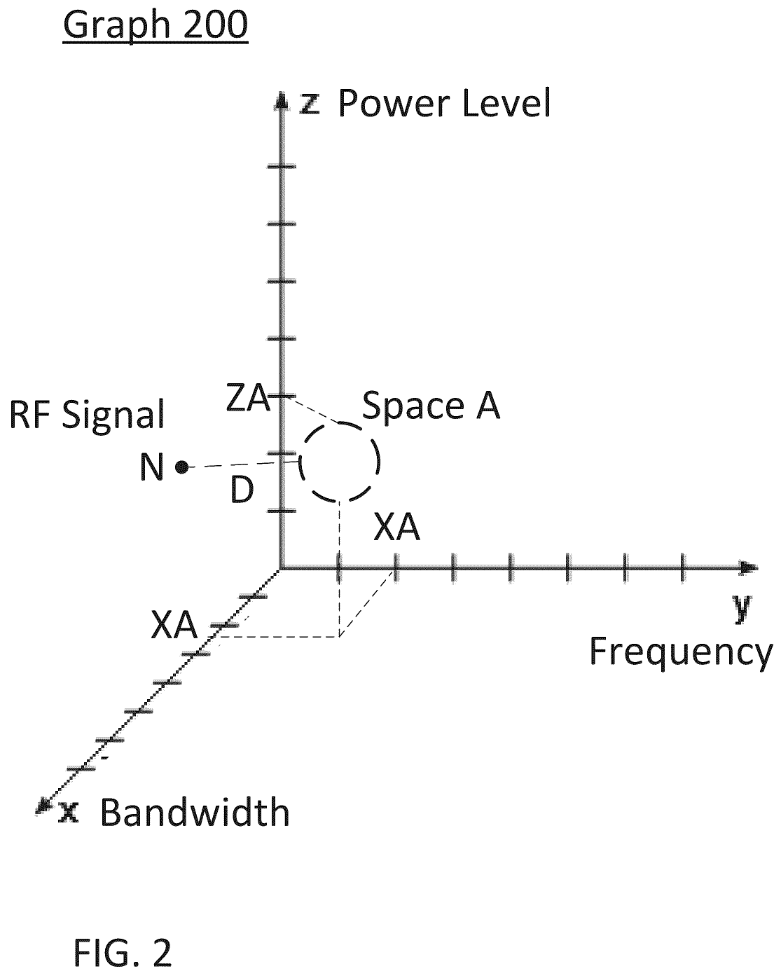

FIG. 2 is a graph 200 of an example multidimensional space in which RF radiation may be encoded, according to some embodiments.

As described herein, RF anomaly detection may include obtaining a multidimensional encoding of characteristics of an RF signal, which may be performed for example by computer 130 in FIG. 1. One example multidimensional encoding of characteristics of an RF signal is shown as RF Signal N in FIG. 2. For example, RF Signal N may have been received by an RF sensor 120 of FIG. 1, and may have characteristics such as a power level, frequency, and bandwidth. For instance, such characteristics may be determined onboard the RF sensor and/or by computer 130. In FIG. 2, the multidimensional space is shown with three visible axes, including an x axis corresponding to bandwidth, a y axis corresponding to frequency, and a z axis corresponding to power level. It should be appreciated that other axes may be present though not shown.

In some embodiments, a multidimensional encoding may be generated using digital samples of RF radiation received by an RF sensor in an operating environment, such as RF sensor 120 in operating environment 102 in FIG. 1. For example, a multidimensional encoding of characteristics may be output by a model trained to provide the multidimensional encoding in response to inputting the digital samples, such as may be executed on an RF sensor 120 in FIG. 1. For instance, the model may be trained to encode characteristics of an RF signal into dimensions of the multidimensional space, such as bandwidth, frequency, and power level as shown in FIG. 2. In some embodiments, the multidimensional encoding may consume less memory than a subset of the digital samples the RF sensor 120 received that indicated (e.g., included) the RF signal. For example, the multidimensional encoding may be at least partially lossy, though the model may be trained to preserve characteristics that distinguish the RF signal from other RF radiation, making such an encoding useful for downstream processing such as RF anomaly detection.

In some embodiments, RF anomaly detection may include determining, based on the multidimensional encoding, that the RF signal is anomalous compared to a baseline of multidimensional encodings of characteristics of RF radiation received in the operating environment. For example, the determination may be performed by computer 130 using a multidimensional encoding provided by an RF sensor 120, though in other examples an RF sensor 120 may perform the RF anomaly detection at least in part. One example baseline of multidimensional encodings is shown as Space A in FIG. 2. In some embodiments, baseline multidimensional Space A may be generated based on a plurality of multidimensional encodings of characteristics of baseline RF radiation received from the operating environment. For example, Space A may contain multidimensional encodings of characteristics of RF signals that are included in the baseline. For instance, multidimensional boundaries of Space A may correspond to farthest extremes in each characteristic of the baseline RF signals.

Alternatively or additionally, baseline multidimensional Space A may represent a plurality of multidimensional encodings in aggregate. For example, baseline multidimensional Space A may include a Gaussian mixture of the plurality of multidimensional encodings. In the same or another example, baseline RF radiation from which Space A is generated may be received at predetermined times and in a predetermined frequency range. For example, an initial step of generating a baseline may include observation of RF radiation over a particular frequency range in the operating environment 102 for a predetermined amount of time. Such a baseline may be advantageous for high resolution anomaly detection in some embodiments. In the same or another example, the baseline RF radiation from which Space A is generated may be received at overlapping times and in a plurality of different frequency ranges. For example, an alternative or additional step of generating a baseline may include observing RF radiation in the operating environment 102 over a plurality of frequency ranges in predetermined periodic time windows. Where overlapping times are used, Space A may include a projected estimation of RF radiation at times other than the overlapping times, the projected estimation based on the baseline RF radiation received at the overlapping times. In some embodiments, observing RF radiation at overlapping times over a plurality of different frequency ranges may be advantageous for generating a baseline to use for low resolution identification a subset of RF data, but is not limited thereto.

In other embodiments, determining that the RF signal is anomalous compared to the baseline may include inputting, at different respective times, the baseline of multidimensional encodings and the multidimensional encoding of characteristics of the RF signal into a model and determining that the RF signal is anomalous based on an output from the model. For example, Space A may be stored (e.g., by computer 130) and RF Signal N may be input together with Space A to a model trained to output a similarity score and/or classification between RF Signal N and Space A based on the characteristics encoded therein. According to various embodiments, the model may be selected from a group consisting of a sphericity model, an autocorrelation model, and a quadratic time-dependence model. For example, sphericity testing may be performed on collected encodings and corresponding digital (e.g., IQ) samples, generalized likelihood ratio tests on Yule-Walker autocorrelation estimates, and/or trained pre-whitening transformations applied in Whittle quadratic statistic tests. These methods may permit constant false alarm rate (CFAR) anomaly detection with an implied baseline as opposed to an explicitly defined baseline. Some of these methods, such as learned pre-whitening, may be expressed via Bayesian deep learning to support gain invariant detection for low-SNR signals.

Finally, the baseline free anomaly detection methods may be deployed on various technologies including GPU, CPU and FPGA based computers.

In the illustrated embodiment, Space A is shown as occupying a range of values in the y and z dimensions while having a single value in the x dimension, but it should be appreciated that Space A may occupy any range of values in any dimensions. For example, a single value in each dimension may be occupied by a single encoding of characteristics, which may be an encoding of a synthetic representation of an aggregate of RF signals in the baseline. In the same or another example, a plurality of synthetic representations of RF signals may provide an aggregate, such as resulting in fewer synthetic encodings than encoded RF signals represented in the aggregate.

In some embodiments, determining that the RF signal is anomalous may include determining that a multidimensional distance between the multidimensional encoding of characteristics of the RF signal and the baseline of multidimensional encodings exceeds a predetermined multidimensional distance. For example, in FIG. 2, the illustrated multidimensional encoding of RF Signal N is at a multidimensional distance D from multidimensional Space A, which may exceed a predetermined multidimensional distance from Space A. For instance, the multidimensional distance D may incorporate distances within each dimension, such as distance XA between RF Signal N and Space A along the x axis, distance YA between RF Signal N and Space A along the Y axis, and distance ZA between RF Signal N and Space A along the Z axis. In some cases, the multidimensional distance D may be a Euclidean distance, while in other cases a distance in which some dimensions are weighted with respect to others may be used. According to various embodiments, the predetermined multidimensional distance may be set based on user specification, user action (e.g., input in a graphical user interface), and/or a default configuration for RF anomaly detection.

In some embodiments, the RF signal determined to be anomalous may be a deviated version of a baseline RF signal in the RF radiation included in the baseline that has deviated in operating condition by more than a predetermined extent. For example, the multidimensional distance D may embody the predetermined extent to which a baseline RF signal may deviate before being considered anomalous. For instance, the extent of deviation may take into account expected deviations in frequency, power level, bandwidth, and/or time of reception. In some embodiments, deviated versions of RF signals may be received from the same RF source, which may cause at least some encoded characteristics to be similar while others are different. In some embodiments, deviated versions of RF signals may be received from a different RF source that has transmitted an RF signal included in the baseline, though the received RF signal may have some similar characteristics such as frequency and bandwidth while having a different characteristic such as power level (e.g., due to the different RF source being at a different distance from the RF sensor 120 than the previous RF source) from the baseline RF signal transmitted by the previous RF source. In some embodiments, the RF signal determined to be anomalous may have been transmitted by an RF source that has not transmitted RF radiation included in the baseline.

In some embodiments, determination that a multidimensional distance between the multidimensional encoding of characteristics of the RF signal and the baseline of multidimensional encodings exceeds a predetermined multidimensional distance may include various comparison algorithms. Example comparison algorithms include covariance matrix estimation methods such as: Graphical lasso covariance estimation, Minimum covariance determinant, and Empirical covariance estimation methods. As an alternative or in addition to comparison algorithms, other comparison techniques such as metric thresholding methods may be applied, for instance based on: Mahalanobis measures, Euclidean measures, and Cosine measures. An additional technique includes Analysis of Variance methods (ANOVA) such as Multiple Analysis of Variance methods (MANOVA). An additional comparison technique includes density estimation based on: Radial-Basis Kernel Density Estimation, Gaussian Kernel Density Estimation, and Maximum likelihood density estimation. Further techniques include:

Local outlier factor, Isolation Forest methods, One-Class Support Vector Machines, Recurrent Neural networks, Variational and Non-Variational Neural Networks, and Bayesian networks such as hidden Markov models.

While FIG. 2 shows an example multidimensional space using classical RF signal characteristics, other examples described herein may include machine readable features as encoded characteristics.

Alternatively or additionally, in some embodiments, comparison in a multidimensional space may be performed in a space that is compressed with respect to the multidimensional space into which RF signals are encoded (e.g., onboard an RF sensor). For example, the compressed space may be created using statistical compression processes that project contents of multiple dimensions into fewer dimensions, such as where the compressed dimensions are relatively statistically insignificant for all encodings to be compared.

### IV. Example RF Anomaly Detection Using Identified Subset of RF Data

As described above, some aspects of the present disclosure relate to performing anomaly detection on an identified subset of RF data over a frequency range and/or time period of reception. In some embodiments, a multi-step process involving multiple types of measurements and potentially multiple RF sensors may be used. In one implementation, an RF system configured for multi-channel reception (e.g., using the same and/or multiple RF sensors) may have a first receive channel configured to sweep a predetermined spectrum and/or time period as fast as possible, and input a limited set of resulting RF data to an algorithm designed to identify a subset of the spectrum and/or time period as, for example, exceeding a predetermined power spectral density as compared to aggregate baseline measurements. This step can be the basis for instructing another channel to track the potential anomaly and collect more detailed (e.g., higher resolution) measurements of the signal as a subsequent step for additional downstream verification. Alternatively or additionally, the subsequent step may be performed directly on the subset of RF data identified in the earlier step.

In some implementations, a first receive channel may be implemented using a separate RF sensor 120 configured to instruct another RF sensor 120 over a network 140. The RF sensor used at the earlier step may have more compute resources available than the RF sensor 120 used at the subsequent step and/or other RF sensors 120 in the system 100 to allow it to identify signals more quickly, such as through ingesting a wide instantaneous bandwidth and/or utilizing primarily processed data such as a power spectral density. Alternatively or additionally, the RF sensor used at the earlier step may have fewer compute resources available, such as may be used to perform a Fourier Transform and processing of classical signal characteristics rather than executing a model.

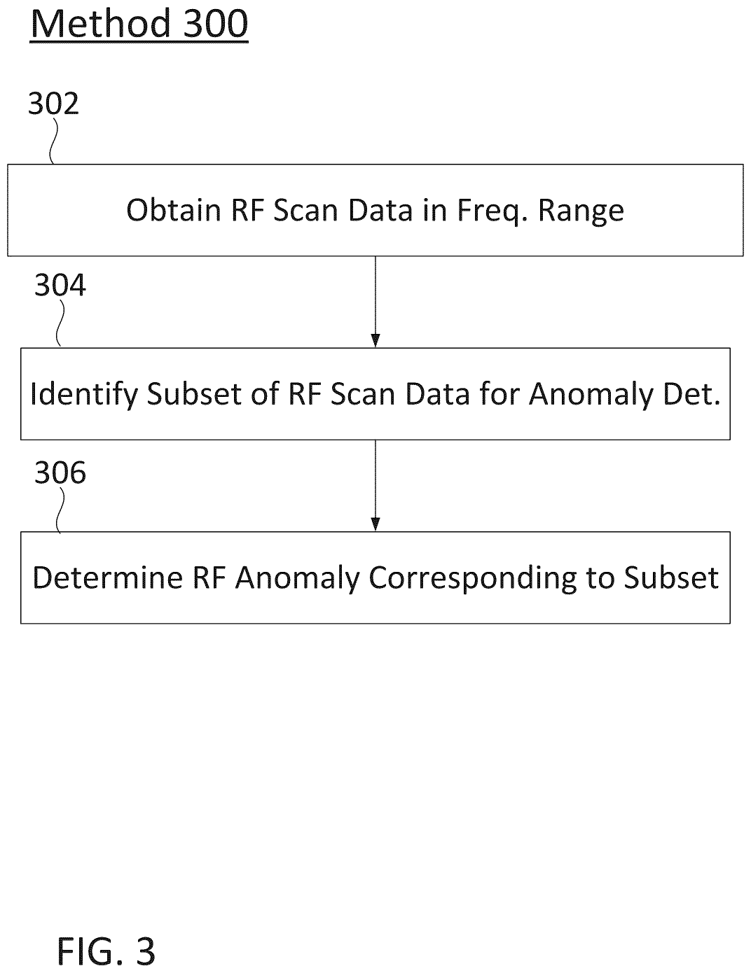

FIG. 3 is a flow diagram of an example method 300 of RF subset identification and RF anomaly detection within the identified RF subset, according to some embodiments.

As described herein, RF anomaly detection may include obtaining RF data of a first frequency range over which an RF sensor 120 of the RF system scans for RF radiation, such as shown at step 302 in FIG. 3. In some embodiments, obtaining the RF data at step 302 may include generating the RF data by the RF sensor 120 based on digital samples of RF radiation in the first frequency range received by the RF sensor and portions of the first frequency range in which no RF radiation was received by the RF sensor. For example, the RF data may indicate power spectral density over the first frequency range, which may indicate the presence and absence of RF radiation and/or particular RF signals over the first frequency range. In other examples, the RF data may provide a multidimensional encoding of the first frequency range or multidimensional encodings of subsets thereof, for instance using a lower resolution encoding than may be used in embodiments that use an encoding at step 306.

In some embodiments, RF anomaly detection may further include identifying a subset of the RF data in which to detect RF anomalies, such as shown at step 304 in FIG. 3. For example, the subset of the RF data may be identified based on having an indication of RF radiation and/or an RF signal present, such as based on an indication of at least a predetermined power spectral density in the subset of the RF data. For instance, where other subsets of the RF data do not indicate RF radiation and/or RF signals, such subsets may not be identified, which may lead to no further anomaly detection within such subsets. In the same or another example, the subset of the RF data may be identified as a region within the first frequency range having a predetermined difference in power spectral density, time period of reception, and/or bandwidth (e.g., signal bandwidth) with respect to a baseline of RF data for that region. In some embodiments, the subset of the RF data identified at step 304 may include RF radiation in a second frequency range contained within the first frequency range.

In some embodiments, identifying the subset of the RF data at step 304 may use less computing power per unit of frequency over the first frequency range than determining the presence of the RF anomaly uses over the second frequency range. For example, the second frequency range may be smaller than the first frequency range, so as to potentially contain less data per unit frequency than the RF data as a whole. Alternatively or additionally, the resolution of characteristics (e.g., dimensionality of the encoding space) used for comparing to a baseline for a region of the first frequency range may be smaller than used for detecting the presence of an RF anomaly at step 306. In examples, where the first frequency range is alternatively or additionally associated with a first time period of reception, then identifying the subset may use less computing resources per unit of time than determining the presence of the RF anomaly uses over a second time period of reception of the subset of the RF data that is a subset of the first time period of reception.

In some embodiments, a metric of computing power per unit of frequency and/or time may be based on any or each of energy, processing threads, memory consumption, and/or hardware cost used to identify a subset of RF data and, by comparison, to perform anomaly detection corresponding to the subset of the RF data. This metric may be determined by dividing the same amount of computing power over the frequency range and/or time period duration of the respective dataset. For instance, using the same amount of computing power over different frequency ranges and/or different time period durations results in a different amount of computing power per unit of frequency and/or time. As described herein, using fewer computing resources to identify a subset of RF data as potentially indicating an anomaly, and subsequently performing anomaly detection corresponding to the subset may reduce the amount of computing resources used overall, such as by using less computing power per unit of frequency and/or time in the earlier identification step.

In some embodiments, identification of a subset of the RF data may be performed on a filtered set of frequency bins. In an implementation using multidimensional encodings, or example, the multidimensional space of baseline RF data to match against the RF data may be limited to a set window around the center frequency of the new measurement(s). For example, the comparison space of a new measurement collected at 900 MHz may be limited to only measurements previously received 50 MHz above and/or below 900 MHz. In this manner, the identification process can become more sensitive to new RF sources with a waveform that previously appeared in the baseline. For example, a new single measurement of an out-of-band Wi-Fi® signal collected at 1.6 GHz could still be flagged as an RF anomaly even if the baseline contains other Wi-Fi® signals collected at 2.4 GHz by limiting the space of comparison to 100 MHz on either side of the 1.6 GHz signal. These frequency bins may be regularly spaced (e.g. bins with a standard width of 200 MHz), and/or informed by user input parameters and/or predefined (e.g., FCC) frequency allocations. It should be appreciated that other characteristics in a multidimensional space may be similarly limited as described herein for frequency.

In some embodiments, RF anomaly detection may further include determining a presence of the RF anomaly corresponding to the subset of the RF data by comparing a representation of RF radiation corresponding to the subset to a baseline of RF radiation received by the RF system, such as shown at step 306 in FIG. 3.

In some embodiments, determining the presence of the RF anomaly at step 306 may include generating a multidimensional encoding of characteristics of RF radiation corresponding to the subset of the RF data and comparing the multidimensional encoding to a baseline of multidimensional encodings of RF radiation received by the RF system. For example, step 306 may be performed in the manner described herein including in connection with FIG. 2. For instance, obtaining the multidimensional encoding of characteristics of the RF signal N as described in connection with FIG. 2 may include identifying, within RF data of a first frequency range over which the RF sensor(s) 120 scan(s) for RF radiation, a second frequency range contained within the first frequency range and indicated as including RF radiation, and/or a second time period of reception contained within a first time period of reception over which is scanned. In some embodiments, the RF signal may be identified within RF radiation data of the RF radiation in the second frequency range and/or second time period of reception. In some embodiments, generating the multidimensional encoding of characteristics of the RF signal N may use digital samples of the RF radiation received by the RF sensor(s).

While FIG. 3 provides an example where the RF data is of a first frequency range, in some embodiments, the RF data may be alternatively or additionally of a first time period of reception. For example, the RF data may include a larger time period of reception and or a plurality of time periods of reception and the subset may include RF radiation in a subset of the larger time period of reception and/or a subset of the plurality of time periods of reception. It should be appreciated that advantages of the present techniques may be obtained similarly from identifying a subset of time period(s) as an alternative and/or in addition to frequency subsets.

### V. Example Interactive User Control of RF Anomaly Detection

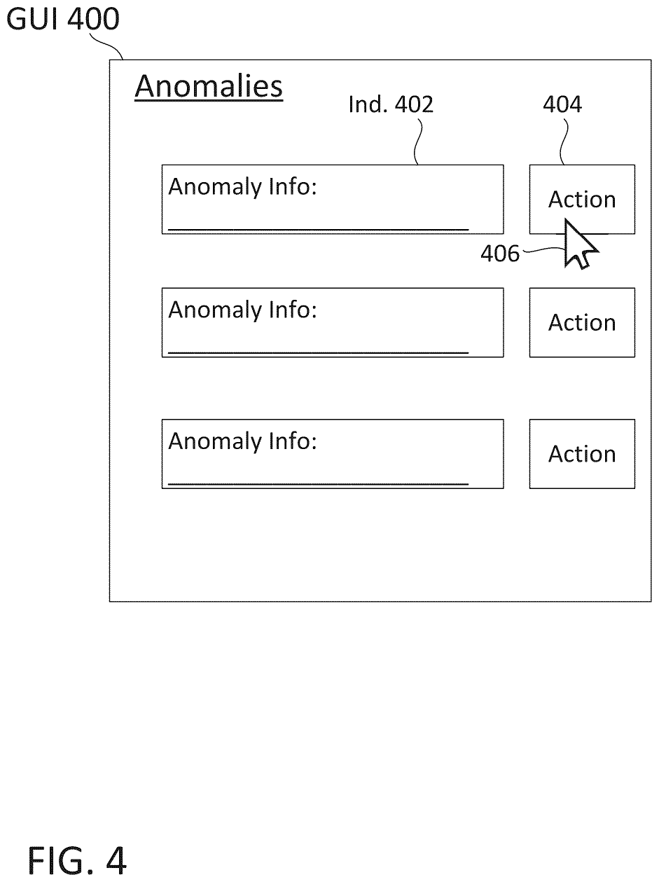

FIG. 4 is a view of an example interactive graphical user interface 400 for RF anomaly detection control, according to some embodiments.

As described herein, some aspects relate to controlling RF anomaly detection by initiating an action in response to selection of an option displayed to a user in a graphical user interface in along with an indication of an RF signal determined to be anomalous compared to a baseline. In some embodiments, the graphical user interface 400 may be generated by computer 130 of FIG. 1 or another system component configured to perform RF anomaly detection. For example, the graphical user interface 400 may be accessible from a user device 150. In some embodiments, the graphical user interface 400 may be generated locally at a user device 150 and populated with data obtained from computer 130, such as via an application programming interface.

In some embodiments, controlling RF anomaly detection in an RF system may include displaying, in a graphical user interface to a user, an indication of an RF signal received by the RF system and determined to be anomalous compared to a baseline. For example, as shown in FIG. 4, the graphical user interface 400 includes an indication 402 of an RF signal received by the RF system. For instance, the indication 402 may include an overview of characteristics of the RF signal, such as frequency, power level, bandwidth, modulation, time of reception, and/or other aspects of the RF signal.

In some embodiments, controlling RF anomaly detection may further include displaying, in the graphical user interface, an option selectable by the user to initiate an action by the RF system associated with the RF signal. For example, as shown in FIG. 4, the graphical user interface 400 includes an option 404 that is selectable by the user to initiate an action. In the illustrated example, the option 404 is selectable by the cursor 406 of the computer system accessing the graphical user interface 400, but other modes of selecting the option are possible such as using a touch screen, selector, voice command, and/or automated chat interface.

In some embodiments, the option 404 may include adding the RF signal to the baseline. For example, the action may include adding a multidimensional encoding of the RF signal to the baseline. For instance, by adding the multidimensional encoding of the RF signal to the baseline, future execution of RF anomaly determination may result in the RF signal not being indicated as anomalous in the graphical user interface 400. In the same or another example, the baseline may be further generated based on multidimensional encodings of characteristics of RF radiation received by the RF system. For instance, the baseline may include encodings of RF signals, such as in a space occupied by the encodings of the RF signals and/or in aggregate, such as using a Gaussian mixture and/or one or more synthetic encodings as described herein including in connection with FIG. 2.

In some embodiments, the option 404 may include ignoring the RF signal. For example, in response to a further indication that the RF signal has been received by the RF system, display of a further indication of that RF signal in the graphical user interface 400 may be omitted. For instance, the RF signal received at a different time (e.g., in the future or in a different period of historical data) may be determined to be anomalous by the system (e.g., computer 130) but an indication may not be displayed in the graphical user interface 400. Alternatively or additionally, a second RF signal that is determined to be anomalous may be ignored, with a first multidimensional encoding of the RF signal being within a predetermined multidimensional distance from a second multidimensional encoding of the second RF signal. For example, the second RF signal may be very similar to the RF signal that was ignored, as indicated by the multidimensional distance between the respective encodings, and thus an indication of the second RF signal in the graphical user interface 400 may be omitted. It should be appreciated that omitting display of an indication of the RF signal may be in an anomalies tab of the graphical user interface 400, and that such an indication may be displayed elsewhere in the graphical user interface 400 such as in an RF signals tab, a baseline signals tab, and/or a log of RF radiation.

In some embodiments, the option 404 may include obtaining digital samples of the RF signal. For example, the digital samples of the RF signal may be stored in memory of the RF system, such as memory of an RF sensor 120 and/or computer 130. In the same or another example, the option 404 may include instructing the RF system to store the digital samples in memory, such as due to indicating an anomaly. In some embodiments, the option 404 may include instructing an RF sensor of the RF system to provide digital samples of RF radiation associated with the RF signal. For example, the action may include instructing the RF sensor(s) 120 to provide digital samples of RF radiation in a frequency range and/or time period of reception of the RF signal (e.g., for a signal that is received periodically). For instance, the digital samples may be generated at the RF sensor 120 following receipt of the instruction, and/or digital samples may be provided from memory of the RF sensor 120 in response to the instruction. In some embodiments, the RF signal may have been received by a first RF sensor 120 of the RF system 100, and instructing the RF sensor(s) to provide the digital samples of the RF radiation may include instructing a second RF sensor 120 of the RF system 100. For example, a different RF sensor 120 of the RF system may be instructed to provide digital samples than the RF sensor that received the RF signal indicated in graphical user interface 400. In some embodiments, instructions may be sent over a communication network such as network 140

In some embodiments, the option 404 may include communicating an alert over a communication network indicating the RF signal determined to be anomalous. For example, the alert may be communicated in response to a further indication that the RF signal was received by the RF system. For instance, the further indication may correspond to reception of the RF signal at a later time, and/or may correspond to reception of the RF signal at a different time during a scan of historical data (e.g., offloaded from an RF sensor). According to various embodiments, the alert may be communicated to another computer system, a mobile device, and/or other such computing devices, and/or may be communicated over network 140. In some embodiments, the alert may include information about the RF anomaly. For example, reception of such an alert (e.g., at an RF jamming system) may trigger transmission of a jamming signal in the time and/or frequency range of the RF anomaly, which may be assisted using information about the anomaly (e.g., frequency range and/or time of reception).

In some embodiments, the option 404 may include adding a multidimensional encoding of the RF signal to a grouping of associated multidimensional encodings. For example, as described herein, groupings of multidimensional encodings may be set based on multidimensional distance between encodings and/or by user action. For instance, when a user adds a new multidimensional encodings to a grouping, future determinations of whether to associate a new RF signal to the grouping may take into account the added multidimensional encoding, for example since the new RF signal may have a multidimensional encoding that is within a predetermined multidimensional distance of the added multidimensional encoding, and/or may be within a predetermined multidimensional distance of an aggregate of the grouping that takes into account the added multidimensional encoding.

In some embodiments, the option 404 may include creating a new grouping of associated multidimensional encodings including the multidimensional encoding. For example, new multidimensional encodings may be added to the new grouping when determined to be within a predetermined multidimensional distance of the encoding of the RF signal, and/or an aggregate of the grouping (e.g., once other multidimensional encodings have been added by determination and/or by a user).

In some embodiments, controlling RF anomaly detection may further include responding to selection of the option by the user by initiating the action by the RF system associated with the RF signal, such as described above in connection with the example actions listed.

In some embodiments, a multidimensional encoding of the RF signal may be generated based on digital samples of RF radiation received by an RF sensor 120 of the RF system and including the RF signal, such as described herein including in connection with FIG. 2. For example, the RF signal may be determined to be anomalous by comparing the multidimensional encoding to the baseline, the baseline being generated based on multidimensional encodings of RF radiation received by the RF system, such as described herein including in connection with FIG. 2.

### VI. Example Distributed System Implementations of RF Anomaly Detection

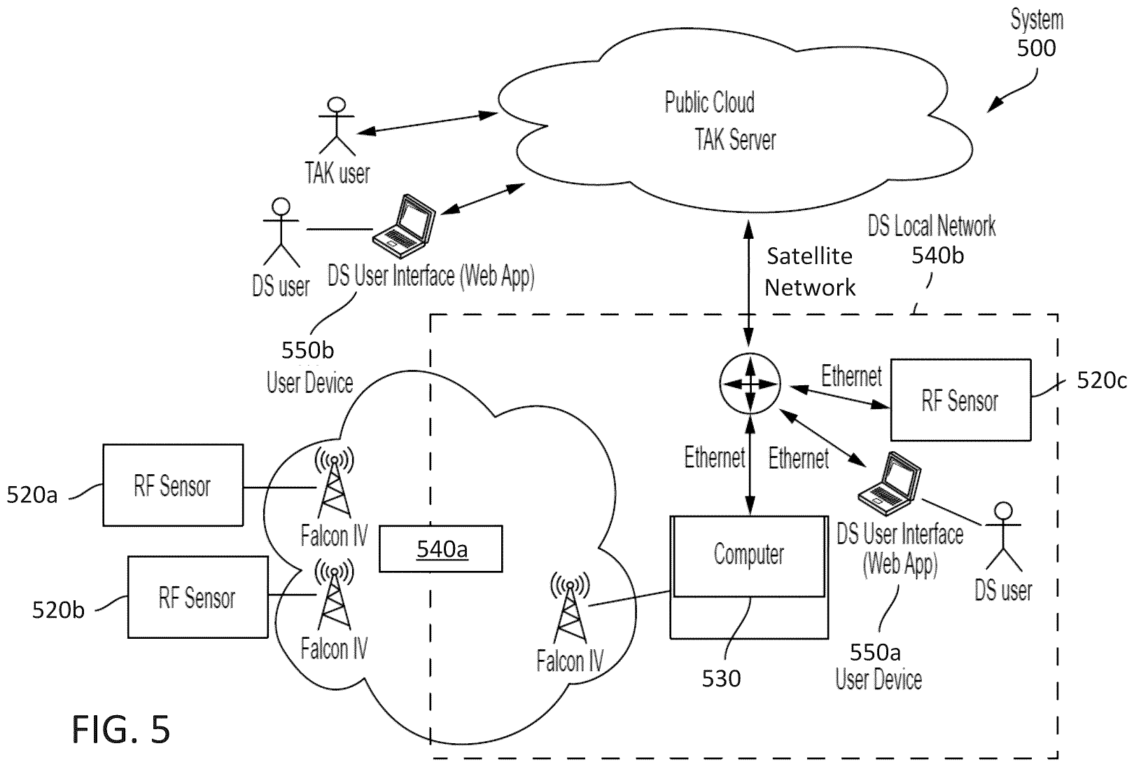

FIG. 5 is a schematic diagram of an example system 500 for RF anomaly detection, according to some embodiments.

In some embodiments, system 500 may be configured as described herein for system 100. For example, system 500 includes RF sensors 520a, 520b, and 520c which may be configured as described herein for RF sensor(s) 120. As another example, system 500 includes computer 530, which may be configured as described herein for computer 130. As another example, system 500 includes networks 540a and 540b, which may be configured as described herein for network 140. As yet another example, system 500 includes user devices 550a and 550b, which may be configured as described herein for user device(s) 150.

As shown in FIG. 5, the system 500 includes an interconnection of multiple networks 540a and 540b. For example, network 540a may be a network link (e.g., LoRaWAN) through which two RF sensors 520a and 520b communicate with a computer 530, and network 540b may be a LAN through which another RF sensor 520c and user devices 550a and 550b communicate with the computer 530 (e.g., via an interface). In the illustrated example, the computer 530 may be configured to process representations of RF radiation received by the RF sensors 520a, 520b, and 520c and manage a database of RF signals detected by the RF sensors 520a, 520b, and 520c, and/or associated characteristics and the computer 530 may be further configured to execute an interface (e.g., application programming interface and/or graphical user interface) permitting the user devices 550a and 550b to interact with (e.g., control, access, and/or set) aspects of the system (e.g., reports of detected RF signals, categories associated with the RF signals, actions, etc.), such as RF anomaly detection.

As shown in FIG. 5, user devices 550a and 500b may be configured to interact with the data reported and/or stored by computer 530 directly, such as in the case of the user device 550a connected via ethernet to the same network 540a as the computer 530, or indirectly, such as in the case of the user device 550b connected via a server and satellite connection to the network 540b. While user devices 550a and 550b are shown as computer systems, mobile devices may be used (e.g., a mobile device of the TAK user, which is not shown). The illustrated example provides access for the user device 550a via a public cloud interface, but access may be provided with private cloud in addition or alternatively.

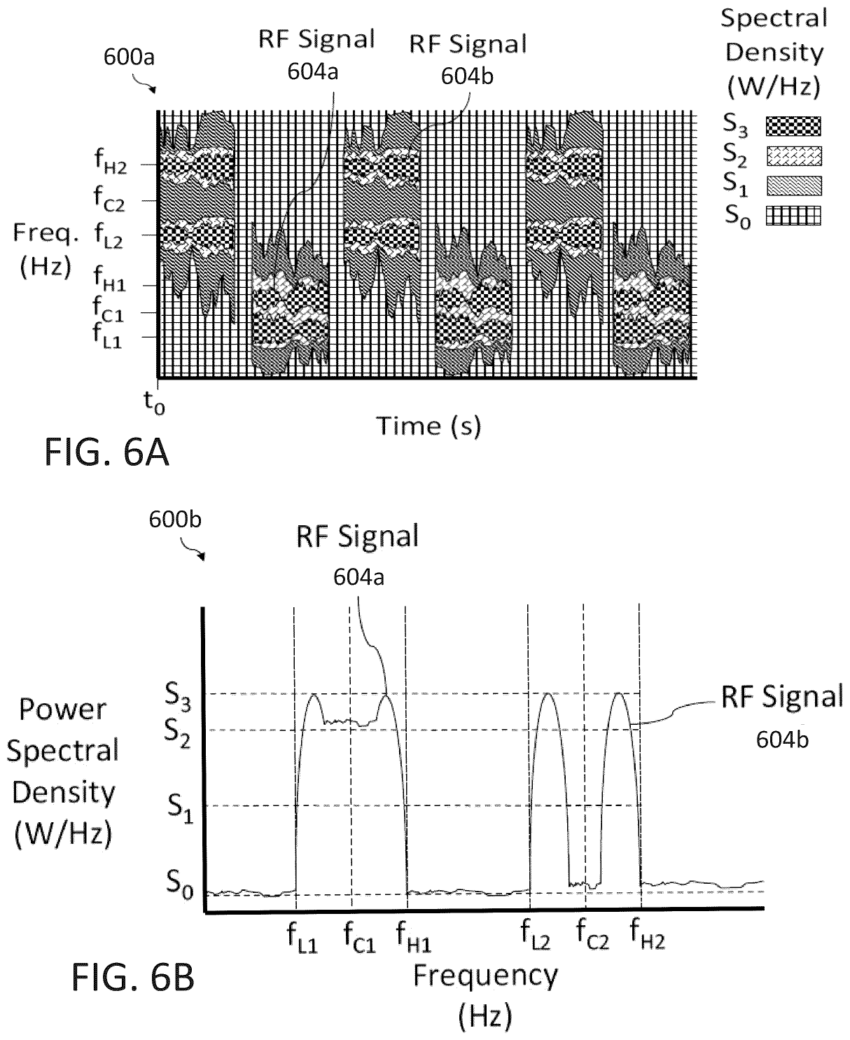

As described herein, some aspects of the present disclosure relate to performing anomaly detection on an identified subset of RF data over a frequency range and/or time period of reception. In some embodiments, identifying the subset of RF data includes identifying a second frequency range and/or time period as including RF radiation, an example of which is described herein in connection with FIGS. 6A-6B.

FIG. 6A is a spectrogram 600a of example RF signals received over time, according to some embodiments. FIG. 6B is a graph 600b of power spectral density of the example RF signals of FIG. 6A, according to some embodiments.

In some embodiments, RF radiation received by one or more RF sensors 120 may include RF radiation, which in turn may include one or more RF signals, such as RF signals 104a and 104b shown in FIGS. 6A and 6B. It should be appreciated that RF radiation that does not take the form of a data-carrying signal may be indicated similarly to an RF signal, for example in the form of unintentional emissions from malfunctioning equipment.

In some embodiments, the spectrogram 600a and/or power spectral density shown in graph 600b may be obtained by a processor of an RF sensor 120 based on digital samples of received RF radiation. For example, the RF sensor 120 may be configured to perform a DFT on digital samples of RF radiation received by an antenna of the RF sensor, such as directly or after the RF radiation has been digitally sampled, spectrally filtered, I/Q sampled, and/or demodulated by RF front-end circuitry and generated as RF radiation data. In some embodiments, the power spectral density of RF radiation received at the processor may be at least partially filtered compared to the RF radiation received at the antenna. Alternatively or additionally, the processor may be configured to filter out at least a portion of the RF radiation prior to identification of a subset of the RF radiation data. In some embodiments, the power spectral density and/or spectrogram may be generated by computer 130, such as using digital samples received from an RF sensor 120.

As shown in FIGS. 6A-6B, each RF signal 104a and 104b may have a center frequency fC and an operating frequency band defined from its uppermost frequency fH and lowermost frequency fL. For example, in graph 600b, RF signal 104a is shown as a dual sideband reduced carrier (DSB-RC) signal, with peak power spectral density S3 in the sidebands of the operating frequency band between center frequency fC1 and uppermost frequency fH1 and between center frequency fC1 and lowermost frequency fL1, and with at least power spectral density S2 at the center frequency fC1. Also shown in graph 600b, RF signal 104b is shown as a dual sideband suppressed carrier (DSB-SC) signal, with peak power spectral density S3 in the sidebands of the operating frequency band between center frequency fC2 and uppermost frequency fH2 and between center frequency fC2 and lowermost frequency fL2. In this example, the minimum power spectral density S0 of RF signal 104b may be approximately 0 W/Hz at center frequency fC2, though the minimum power spectral density S0 will usually be nonzero due to the presence of noise in the operating environment 102 in which RF sensor 120 is positioned. In some embodiments, identification of a time and/or frequency range may take into account at least some amount of noise, as changes in received noise may indicate the presence of an anomaly to be detected using a subsequent anomaly detection process.

In some embodiments, RF radiation in a time and/or frequency range may be used (e.g., by an RF sensor 120 and/or computer 130) to identify the time and/or frequency range as of interest for anomaly detection. For example, identifying a second frequency range and/or time period as including RF radiation may include determining that RF radiation data of RF radiation in the second frequency range and/or time period has at least a predetermined power level (e.g., peak and/or average power spectral density). For instance, the predetermined power level may be the same across the time and/or frequency range and/or may be specified for a region within the time and/or frequency range. In the same or another example, the RF radiation may be determined as deviating in characteristics (e.g., time, frequency, bandwidth, and/or peak and/or average power spectral density) from a baseline. For instance, the baseline used for identifying a time and/or frequency range may be smaller and/or lower resolution than a baseline used for anomaly detection, which may result in low compute resources being needed per unit time and/or frequency to identify regions of interest for (e.g., high resolution) anomaly detection.

In some embodiments, determining the presence of an RF anomaly (e.g., by computer 130) may be performed using RF radiation data obtained from the identified subset of the RF data. For example, where the RF radiation data indicates that the time and/or frequency range that includes the RF radiation data is of interest for anomaly detection, then a representation (e.g., encoding) of the RF radiation may be used for anomaly detection. For instance, an encoding may be generated from the same RF radiation data (e.g., digital samples and/or spectrogram) used for identification, and the encoding may be compared to a baseline. Alternatively or additionally, an RF sensor of the system may be instructed (e.g., by computer 130) to provide RF radiation data in the identified frequency range and/or time period, and determining the presence of the RF anomaly may be performed using the RF radiation data in the identified second frequency range and/or time period. For example, the RF radiation data used for anomaly detection may be obtained from the same and/or a different RF sensor 120 than which provided the RF radiation data for identifying a subset, such as at a different time than the RF radiation of the RF radiation data. For instance, an encoding to be compared to a baseline may be generated from RF radiation data obtained after identification of the frequency range and/or time period used for anomaly detection.

In some embodiments, scanning a first frequency range and/or time period to generate RF data for identifying a subset may include rapidly processing a wide range of frequencies and/or times to produce a series of power spectral density data informing the distribution of received signal energy over that frequency range. For example, using methods such as band occupancy measurement, peak detection and noise floor estimation a series of sub-band statistics may be generated from the PSD. These statistics may summarize the qualities of signal energy that may be used to track individual signals present in-band.

In some embodiments, identifying a subset frequency range and/or time period may include feeding the statistics into a Multi-Object Tracking algorithm such as Generalized Labelled Multi-Bernoulli, Poisson Multi-Bernoulli, Multi-Object Kalman filter arrays, Bayesian particle filters or variational approximations of these families. The or similar tracking algorithms may be configured to provide identifiable, evolving states that allow resolution from energy-in-band to true signal presence with measurable error rates.

In some embodiments, models configured to identify a subset frequency range and/or time period may range from simple Gaussian signal representations to Gaussian Gamma Inverse-Wishart conjugate representations that permit multiple observations to be simultaneously tracked as signal features. From this representation, additional signal qualities may be tracked, such as spreads, symbol rates, pulse intervals, sweep rates or sweep directions. The models may further include Jump Markov model representations that permit tracking of signal qualities such as hop rate, hop spread and total transmission extent in band.

In some embodiments, these sets of statistics, including occupied band, peak detection, signal center frequency, signal bandwidth, signal pulse repetition interval, signal spread, signal sweep rate, signal sweep direction, signal hop rate, signal hop spread and signal total transmission extent—along with auto-regressive markers derived implicitly from tracking algorithms—then permit the construction of an observed signal set. This signal set may serve as a baseline, wherein new, untracked signals, changes in tracked signal parameters or disappearance of tracked signals may all indicate RF anomalies. Such a baseline may provide a compact and low compute resource way of identifying a region of interest for anomaly detection over a larger range of time and/or frequency.

From these baselines, as an alternative or in addition to methods stated previously, Gaussian mixture models may be fit to the set of signal representations (e.g., encodings) associated with each track. For example, these models may be fit to an existing baseline using expectation maximization algorithms. Alternatively or additionally, a model may be fit to a baseline while accommodating a large array of signals or other prior RF radiation using variational methods for Gaussian mixtures-such as the mixture of Dirichlet process interpretation.

In some embodiments, Gaussian mixtures may be nested in some hierarchy, permitting the discriminative tracking of signal behaviors under different conditions present in the embedding space.

In some embodiments, an anomaly determination likelihood for each sample may be calculated, for example, using an approximation of mixture distribution Mahalanobis scoring. Alternatively or additionally, silhouette scoring may be employed to uncover samples that best express the modalities embodied by each tracked grouping. Kernel Density Estimation (KDE) scoring may be applied to perform similarity searches on these data to uncover other, similar anomalous or non-anomalous samples.

It should be appreciated that the representation of RF signals 104a and 104b as DSB-RC and DSB-SC, amplitude modulated (AM) signal is one example, and that RF signal(s) 104 could have any type of modulation, such as double sideband full carrier (DSB-FC), and/or with single sideband (SSB) rather than double sideband modulation. Alternatively or additionally, RF signal(s) 104 could be quadrature amplitude modulated (QAM), PM, and/or frequency modulated (FM).

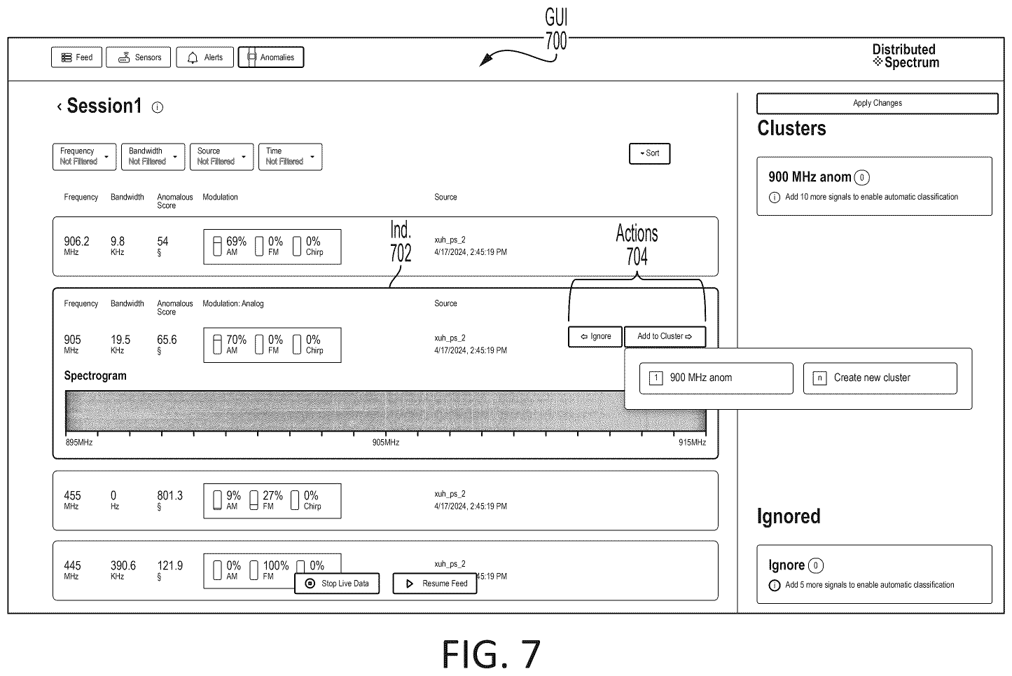

FIG. 7 is a view of a first example interactive graphical user interface screen 700 indicating a detected RF anomaly, according to some embodiments.

As shown in FIG. 7, the graphical user interface screen 700 includes an “Anomalies” tab, which may be included in a graphical user interface that further provides “feed,” “sensors,” and “alerts” tabs. An example session “Session1” is shown listing indications 702 of RF signals determined to be anomalous. The example indications provide measurements with frequency, bandwidth, and modulation information as well as a likelihood of anomaly (“Anomalous Score”), which may be based for example on statistical (e.g., multidimensional) distance between an encoding of an RF signal and a baseline of encodings such as described herein. For the selected measurement, a spectrogram is further shown, as well as options 704 for the user to ignore or add the measurement to a cluster (e.g., grouping). A list of groupings including a “900 MHz anom” cluster (e.g., named by the user) is shown alongside the list of measurements. Also shown alongside the list of measurements is a list of ignored measurements. As shown below the list, options may be displayed to allow a user to select Live Data (e.g., showing measurements substantially in real time as they are made) for viewing, for instance as compared to viewing historical data that has been recorded.

In some embodiments, options providing control parameters exposed in a user interface may allow the user to modify operation of anomaly detection before deployment and/or during operation. One example of a control parameter is the duration of the baseline used and RF sources used to construct the baseline. An alternative or additional example of a control parameter is the size and distribution of frequency bins used to restrict RF sources for comparison within anomaly detection. Another alternative or additional example of a control parameter is the distance threshold in multidimensional space (e.g., for multidimensional encoding implementations) between a candidate signal and a baseline before the candidate signal is flagged as an anomaly.

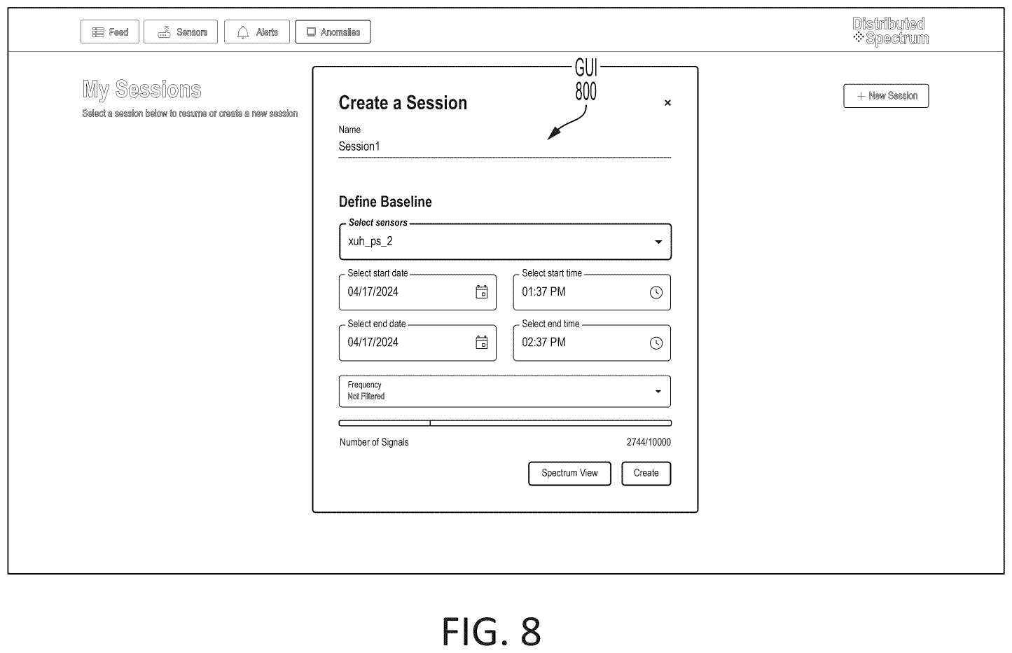

FIG. 8 is a view of a second example interactive graphical user interface screen 800 providing RF anomaly detection controls, according to some embodiments.

The example user interface screen 800 shows options for creating a session, such as may be reached after creating a new session in the screen shown behind the options window. In the create a session screen, a user may name the session and select RF sources and durations in which measurements of those RF sources were captured for including in the baseline for that session. A visual aid showing how many RF signals are included and/or represented in the baseline is shown below the baseline definition options to aid the user in selecting an appropriate number of RF signals to include in the baseline for higher quality anomaly detection.

In some embodiments, an anomaly detection user interface may expose a variety of dashboards that allow users to monitor identified anomalies and track them (e.g., over time and/or in location). In one implementation, anomaly detection techniques may flag new anomalous signals to a user for further downstream action. Information presented may include time of first detection, a visual representation of the signal such as a spectrogram, matches for any candidate RF sources (e.g., previously recognized in the environment) to associate the signal with as suggested by a downstream process (e.g., hosted by computer 130), and/or any extracted characteristics about the signal such as center frequency and/or bandwidth.

In one implementation, an anomaly detection user interface may allow the user to act on any identified anomalies. Example actions include configuring the anomaly detection process to ignore a previously identified anomaly and hide it from view. In some embodiments, the ignore action can also inform the anomaly detection process to flag fewer or no instances of any other similar signals. For example, in multidimensional encoding implementations, measurements that are determined to be anomalous, but which fall within a predetermined multidimensional distance of an ignored anomaly may be automatically ignored. An anomaly detection user interface may also allow the user to track identified anomalies for further analysis by providing a way to create groups of anomalies. For example, once a group has been created (e.g., by the user and/or automatically), a user may be able to sort anomalies into the groups. With enough examples in a user-created group, the anomaly detection module may be able to automatically associate new anomalies with that group based on metrics such as multidimensional distance. While the accompanying illustrations show a minimum of 10 signals for automatic grouping and a minimum of 5 signals for automatic ignore classification, such numbers may vary depending on implementation.

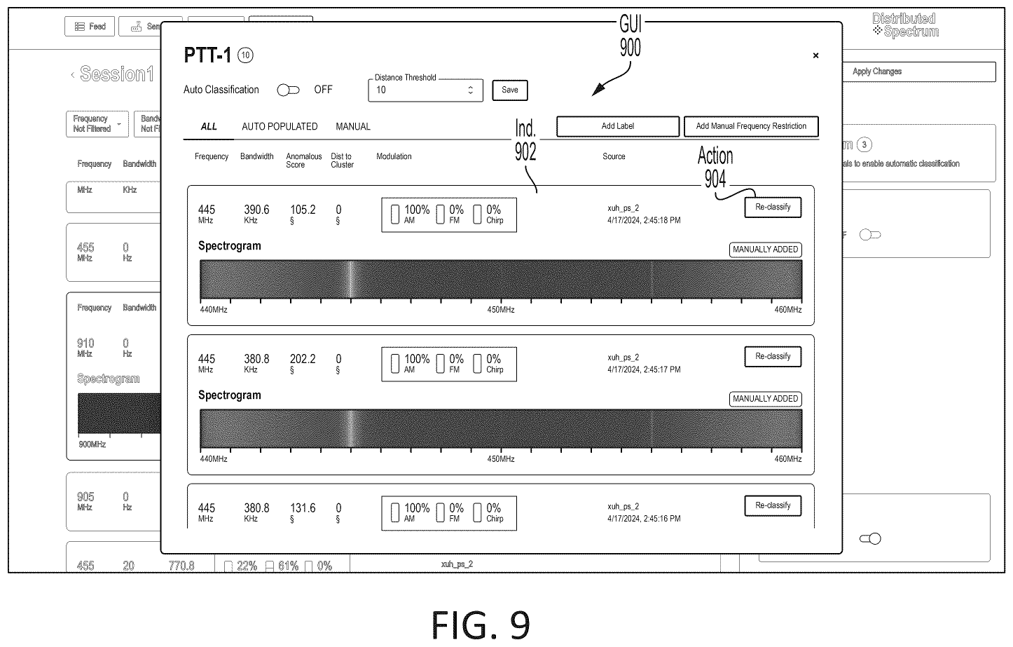

FIG. 9 is a view of a third example interactive graphical user interface screen 900 indicating a detected RF anomaly, according to some embodiments.

The example user interface screen 900 displays a list of measurements within a group, providing similar information as the anomaly detection results screen 700, with additional information specific to the listed group such as distance to cluster. This metric may indicate, for example, the distance from a given measurement to the statistical center of mass of the grouping. As shown in FIG. 9, grouped measurements may be manually and/or automatically added, and the list may be filtered to show automatically added measurements, manually added measurements, or both in the same list as shown in FIG. 9. Further shown in FIG. 9, a user may set a manual frequency restriction which may prevent addition and/or display of measurements in the group outside of the manual frequency restriction.

In some embodiments, an anomaly detection user interface may expose a way for the user to pre-configure automated actions to be provided for selection upon detecting an anomaly.

These actions may include saving signal (e.g. IQ) data and/or data with encoded characteristics (e.g., a multidimensional encoding) of the anomalous signal to storage media, creating a notification such as a text message, or pushing alerts out onto government information systems such as Android Team Awareness Kit (ATAK).

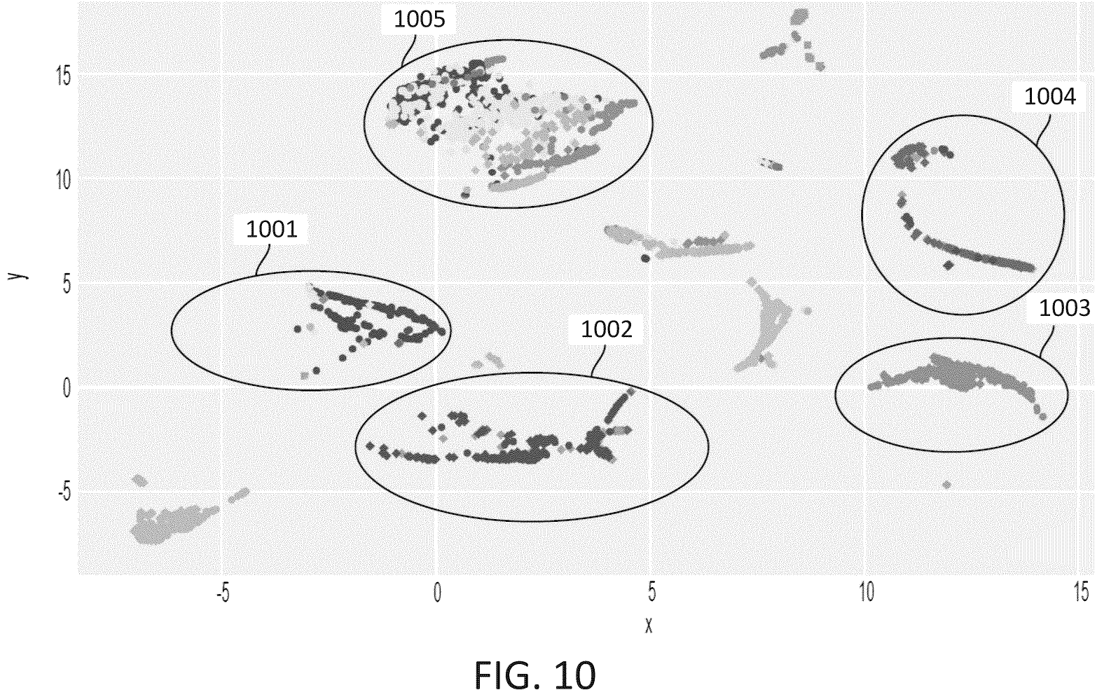

FIG. 10 is a partial graph of a multidimensional space in which RF signals have been encoded and grouped in clusters of predetermined multidimensional distance, according to some embodiments.

As described herein, some aspects of the present disclosure relate to RF anomaly detection using multidimensional encodings of characteristics of RF signals. Some embodiments provide for associating RF signals determined to be anomalous with one another. For example, such associations may be determined based on characteristics encoded in dimensions of the encodings. For instance, similar characteristics may indicate that the associated anomalous RF signals have similar characteristics (e.g., a same RF source or RF source type), which may be the basis for an association such as a grouping.

FIG. 10 shows several groupings 1001, 1002, 1003, 1004, and 1005 of multidimensional encodings of RF signals. In some embodiments, groupings may be determined (e.g., by computer 130) to include multidimensional encodings that are within a predetermined multidimensional distance from one another. Alternatively or additionally, multidimensional encodings may be added to or removed from a grouping by user action (e.g., input to a graphical user interface). Further alternatively or additionally, a grouping of anomalous RF signals may be within a predetermined difference in frequency (e.g., and/or bandwidth) from one another, which may be determined and/or set by user action.

In some embodiments, as part of an RF anomaly detection process, an RF signal determined to be anomalous may be associated (e.g., by computer 130) with at least one other anomalous RF signal. For example, a multidimensional encoding of characteristics of the RF signal may be within a predetermined multidimensional distance from at least one multidimensional encoding of characteristics of the other anomalous RF signal(s). In the example of FIG. 10, the other anomalous signal(s) may include a grouping of anomalous RF signals, such as grouping 1001 in FIG. 10, of which multidimensional encodings of characteristics thereof are within the predetermined multidimensional distance from one another. In this example, the predetermined multidimensional distance may be from the encoding of the RF signal and the grouping of multidimensional encodings of characteristics of the grouping 1001. For instance, the distance may be taken from the closest of the grouping, and/or may be from an aggregate such as a center of mass of the grouping.

In some embodiments, a determination to associate an RF signal with one or more other anomalous RF signals may be based on the multidimensional encoding of the RF signal being within a predetermined multidimensional distance from the other anomalous RF signal(s). Alternatively or additionally, associating the RF signal with the other anomalous RF signal(s) may be in response to an instruction received from a user (e.g., via a graphical user interface) identifying the other anomalous RF signal(s). For example, the instruction may identify a grouping, such as one of the groupings shown in FIG. 10. In some embodiments, associating the RF signal with the other anomalous RF signal(s) may be in response to an instruction received from a user (e.g., via a graphical user interface) that sets the predetermined multidimensional distance, from which a determination based on the multidimensional distance may be made.

In some embodiments, an RF signal may be disassociated from the other anomalous RF signal(s). For example, disassociation may be in response to an instruction received from a user. For instance, the disassociation may occur after an association was determined (e.g., by computer 130) and/or set based on a user instruction for the association.

In some embodiments, the example multidimensional encodings in FIG. 10 may be generated using one or more trained models, such as model 1200 described herein. For example, the multidimensional encodings may be output by a trained model executed onboard an RF sensor having received the RF signals represented in the multidimensional encodings. Alternatively or additionally, the multidimensional encodings may be output by a plurality of trained models onboard a plurality of respective RF sensors having received the RF signals represented by the multidimensional encodings. For instance, where multiple trained models are used, the multiple trained models may be trained, at least in part, using a same set of labeled training data so as to produce multidimensional encodings having similar content in response to receiving similar RF radiation data as inputs.

In some embodiments, the compressed dimension space shown in FIG. 10 may provide a statistical representation of content in multiple dimensions of the illustrated multidimensional encodings. For example, the values shown in FIG. 10 may not correspond to actual values of any particular dimensions of the multidimensional encodings, but rather may correspond to a statistical aggregation of content over multiple dimensions. For instance, multidimensional encodings may be analyzed (e.g., using statistical operations) on content in dimensions of the multidimensional encodings in the aggregate rather than or in addition to using content in any particular dimension or set of dimensions, though in some cases it may be useful to limit the dimensions on which analysis is to be performed, whether for increased computational efficiency and/or where some dimensions may be trained and/or known not to express certain characteristics.

In some embodiments, the compressed dimension space shown in FIG. 10 may be obtained by applying a dimension reduction technique such as a statistical algorithm that identifies and preserves content from dimensions contributing most significantly to the aggregate content of a multidimensional encoding while excising content from dimensions contributing less significantly, such as not at all. In some embodiments, the number of dimensions used in multidimensional encodings described herein may be based at least in part on a number and/or dimensionality of layers of the encoding model, which in turn may be based on the desired accuracy and/or usability of the resulting multidimensional encodings at the expense of model complexity, size in memory occupied by multidimensional encodings at the expense of memory and/or communication network bandwidth, and/or computing resources needed to process the multidimensional encodings downstream.

In some embodiments, multidimensional encodings may be organized into groupings within a shared multidimensional space. For example, groupings may indicate certain similarities in characteristics of the underlying RF signals, such as similar modulation types, pulse rates, probabilities of being analog and/or digital, and/or other characteristics whether well-defined or not. For instance, groupings of multidimensional encodings may result from training a trained model to separate content in dimensions of multidimensional encodings of RF signals having different characteristics, and/or training a trained model to separate and/or associate multidimensional encodings of RF signals desired to be separated and/or associated based on any quantitative and/or qualitative known, expected, and/or intended relationship among the underlying RF signals.

In the illustrated example, five groups of multidimensional encodings are circled within FIG. 10 corresponding to five groupings of multidimensional encodings that may result from training the model(s) that generated the multidimensional encodings. For instance, grouping 1001 may correspond to multidimensional encodings of Wi-Fi signals, grouping 1002 may correspond to multidimensional encodings of analog, FM signals, grouping 1003 may correspond to Bluetooth signals, and grouping 1004 may correspond to cellular signals. In some embodiments, an encoding model may be trained on such signals to produce content in dimensions of the resulting multidimensional encodings that separates the multidimensional encodings as shown in FIG. 10, which may result in newly detected RF signals (e.g., not those on which the model was trained) being populated in similar multidimensional space to that of the RF signals on which the model was trained.

In some embodiments, multidimensional encodings of RF signals may be in a multidimensional space associated with noise, such as due to training an encoding model to associate certain RF radiation data with noise rather than with a particular type of RF signal. For instance, in FIG. 10, grouping 1005 may correspond to noise. It is notable that in FIG. 10, the content of multidimensional encodings within grouping 1005 vary significantly, even with respect to multidimensional encodings that are closely proximate one another in the multidimensional space, as compared to other groups. For example, a trained model may distinguish aspects of random noise in content in dimensions of multidimensional encodings that cause a wide variety of noise radiation (e.g., having very different apparent frequency, modulation, pulse rate, etc.) to occupy similar multidimensional space, such as based on perceived similarity in statistical distribution (e.g., Gaussian distribution) over one or more of such characteristics (e.g., frequency).

It should be appreciated that not all groupings of multidimensional encodings are labeled in FIG. 10 and that some multidimensional encodings could be grouped differently. For instance, some multidimensional encodings may be grouped differently depending on the dimensions of the multidimensional space being analyzed and/or where some of the multidimensional encodings are filtered out by a constraint (e.g., on characteristics of the multidimensional encodings such as frequency), which may impact which characteristics are the basis for grouping multidimensional encodings and/or which characteristics are emphasized in statistically reduced dimensions of the multidimensional encodings.

In some embodiments, multidimensional encodings of RF signals may be compared and/or associated with one another using content in dimensions of the multidimensional encodings, such as the content shown in FIG. 10. For example, an association and/or disassociation among multiple multidimensional encodings may be based on multidimensional distance between the multidimensional encodings in multidimensional space, whether taking into account all or only some of the dimensions of the multidimensional space, and/or when using a compressed dimension space such as shown in FIG. 10. For instance, a Euclidean distance may be used on some or all dimensions of the multidimensional space, and/or in a compressed dimension space, and/or a distance between statistical representations (e.g., using mean and variance of multidimensional encodings in some or all dimensions) of the multidimensional space may be used.

In some embodiments, multidimensional encodings may be associated with in multidimensional space in response to user input. For example, user input may designate a category for RF signals within a predetermined multidimensional distance of a reference RF signal. For instance, categorization around a reference RF signal may be performed in response to the user engaging an option in a user interface to categorize around an RF signal presented in the user interface, which may be set as the reference RF signal. Alternatively or additionally, the user may engage an option in a user interface to categorize on characteristics of RF signals, which may be determined using content in dimensions of the multidimensional encodings. For instance, the user may set thresholds on certain characteristics (e.g., confidence metric of an AM signal and/or bandwidth) that may be used to filter multidimensional encodings, such as when the characteristics are determined using content in dimensions of the multidimensional encodings.

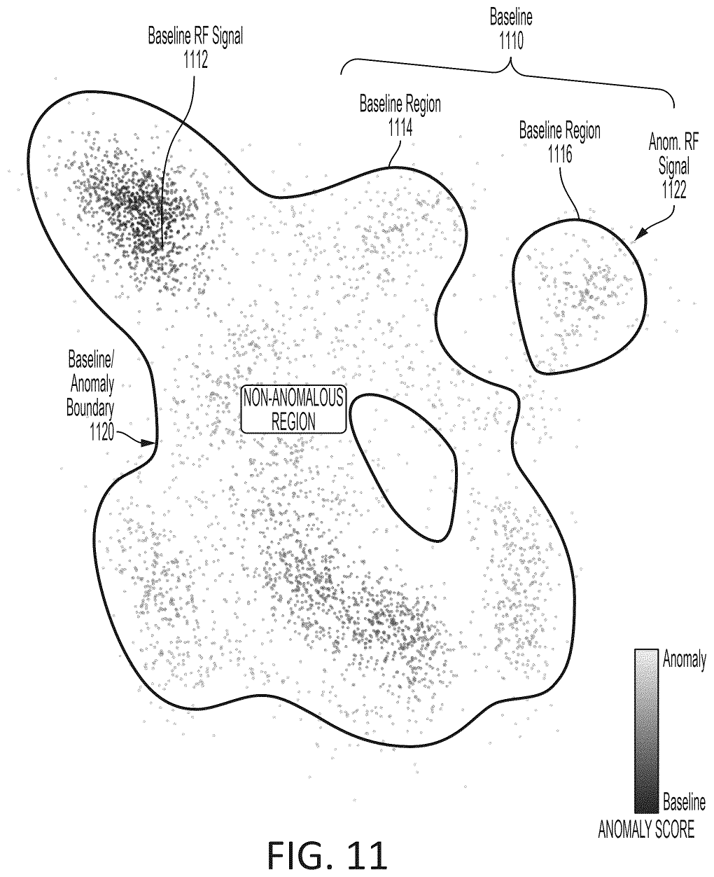

FIG. 11 is a partial graph of a multidimensional space in which an RF baseline has been encoded and RF anomalies have been determined based on a predetermined multidimensional distance, according to some embodiments.

As described herein, some aspects of the present disclosure relate to RF anomaly detection using multidimensional encodings of characteristics of RF signals. One example of a baseline 1110 of multidimensional encodings of characteristics of RF radiation is shown in FIG. 11. In some embodiments, baseline 1110 may consist of multidimensional encodings of characteristics of RF signals, such as a baseline RF signal 1112. Alternatively or additionally, baseline 1110 may consist of a space generated as an aggregate of multidimensional encodings. In the illustrated example of FIG. 11, baseline 1110 is bounded by a boundary 1120, which may limit the space of the baseline 1110 beyond any individual encoding within the space. For instance, the boundary 1120 may represent a predetermined multidimensional distance with respect to an aggregate of the baseline 1110.

In some embodiments, encodings of characteristics of RF signals may be determined as falling outside of the baseline 1110. For example, an encoding of an anomalous RF signal 1122 is shown as being outside of the boundary 1120. For instance, illustrating the encoding of the anomalous RF signal 1122 outside of the boundary may indicate that the anomalous RF signal 1122 is at least a predetermined multidimensional distance from the aggregate of the baseline 1110.

As shown in FIG. 11, the example baseline 1110 includes a first baseline region 1114 and a second baseline region 1116, which are disparate rather than contiguous. For instance, baseline regions 1114 and 1116 may occupy spaces based on encodings that do not share a significant similarity of characteristics, such as a cell phone signal centered at 850 MHz and an 802.11 signal at 5.3 GHz. In some embodiments, a baseline 1110 may be entirely contiguous, and/or may include contiguous and non-contiguous regions. Where a baseline 1110 includes non-contiguous regions, each region may be represented as an aggregate for RF anomaly detection, and/or the aggregate may be constructed from all regions in further aggregate.

In some embodiments, system 100 (e.g., computer 130) may generate a baseline 1110 by observing some frequency band for a period of time. While observing, the system may produce aggregate encodings at specific time and frequency intervals. This set of aggregate encodings may provide a foundation of the baseline 1110. The baseline 1110 may be subsequently transformed with whitening methods such as principal component analysis (PCA) and/or application of some specific rotation and subsequent summarization.

In some embodiments, Gaussian mixture models (GMM) may be fit to the set of aggregate and/or whitened encodings associated with the baseline. Such models may be fit to a baseline using expectation maximization algorithms for example. Such models may be alternatively or additionally fit to a baseline while accommodating a large array of signals or radiation data using variational methods for Gaussian mixtures—such as the mixture of Dirichlet process interpretation. In some embodiments, Gaussian mixtures may be nested in some hierarchy, permitting the discriminative tracking of signal behaviors under different conditions present in the embedding space.

In some embodiments, a likelihood of anomaly determination for a given encoding of an RF signal may be calculated using an approximation of mixture distribution Mahalanobis scoring. Alternatively or additionally, silhouette scoring may be employed to uncover samples that best express the modalities embodied by each tracked grouping. KDE scoring may be applied to perform similarity searches on these data to uncover other, similar anomalous or non-anomalous samples.

In some embodiments, trained parameters of the GMM may serve to greatly compress the baseline definition. For example, this may permit the baseline data to be packaged and transmitted over a network (e.g., from an RF sensor 120 to a computer 130) for use by other anomaly detection systems in the network. This way, a single component (e.g., one RF sensor) may capture a baseline to permit the entire network to perform anomaly detection, though any number of sensors may be used and anomaly detection may be at least partially centralized depending on the implementation. Similarly, multiple components (e.g., RF sensors) may each capture baselines and transmit them (e.g., peer-to-peer or via a server such as computer 130) in the network to support a broader anomaly detection capability than any single component could achieve.

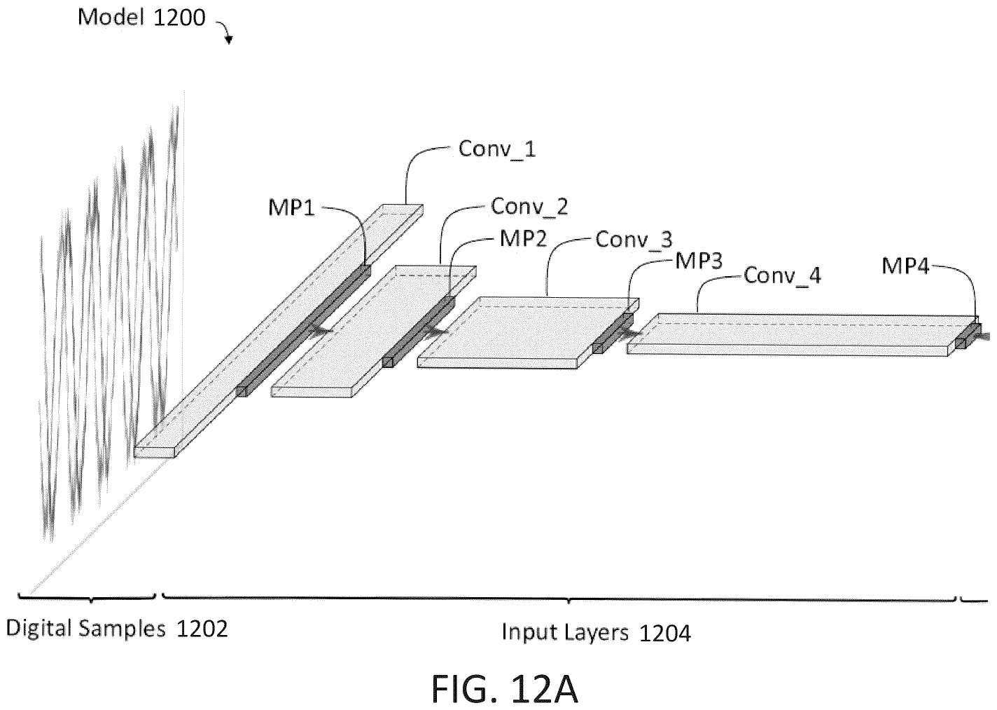

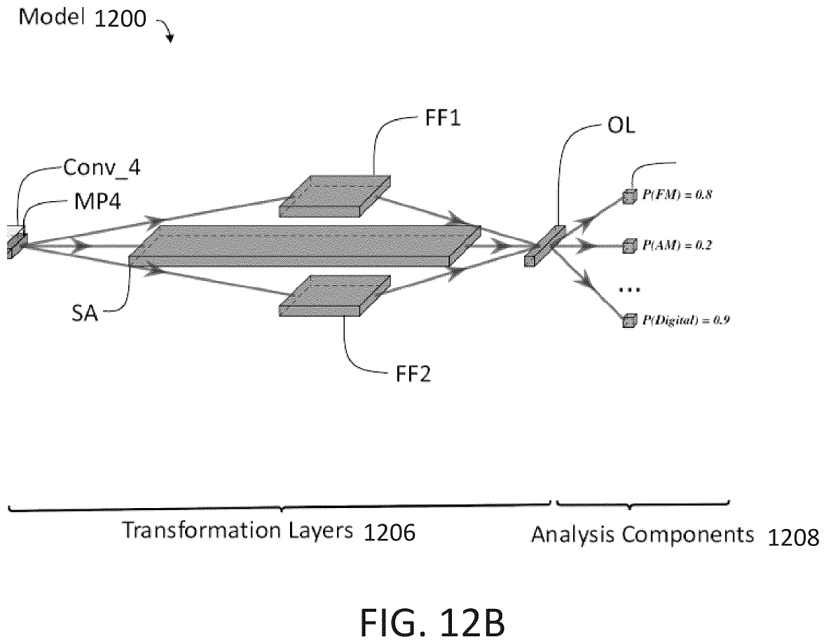

FIG. 12A is a first portion of a block diagram of an example trained model configured to receive RF radiation as an input and to provide a multidimensional encoding of an RF signal in the RF radiation as an output, according to some embodiments.

FIG. 12B is a second portion of a block diagram of the example trained model of FIG. 12A, according to some embodiments.

In some embodiments, an RF sensor 120 of system 100 may be configured to execute one or more trained encoding models on RF radiation data (e.g., digital samples of RF radiation) received via an RF antenna (e.g., onboard an RF sensor). Examples of trained encoding models are described herein. It should be appreciated that computer 130 may be alternatively or additionally configured to execute such encoding model(s).

In some embodiments, model 1200 may be configured to output an indication of characteristics of an RF signal within RF radiation data input to model 1200. For example, model 1200 may be configured to output RF characteristics of the RF signal derived from the RF radiation data, and/or model 1200 may be configured to output a multidimensional encoding of an RF signal detected within the RF radiation data, such as a compressed encoding. For instance, content in dimensions of the multidimensional encoding may indicate characteristics of the RF signal, such as when analyzed with content in dimensions of multidimensional encodings of other RF signals, and/or when input to a trained model trained together with model 1200 to determine characteristics indicated in the content.

In some embodiments, model 1200 may include input layers 1204 (FIG. 12A) and transformation layers 1206 (FIG. 12B). For example, input layers 1204 may be configured to receive and process RF radiation data input to model 1200 and emphasize characteristics of an RF signal within the RF radiation data and transformation layers 1406 may be configured to encode emphasized characteristics of an RF signal within the RF radiation data into content of a multidimensional encoding output from model 1200. Alternatively or additionally, input layers of a trained model may be configured to receive a portion of RF radiation data including an RF signal as indicated by a trained signal detection model, such as a filtered digital sample stream and/or a portion of a spectrogram, depending on the implementation.

In some embodiments, input layers 1204 may be configured to receive and process RF radiation data, such as digital samples 1202 of RF radiation. For example, digital samples 1202 may be received via RF antenna of an RF sensor. For instance, model 1200 may be executed onboard an RF sensor using digital samples of RF radiation received by an RF antenna of the RF sensor and digitized using an SDR, though it should be appreciated that model 1200 need not be implemented onboard an RF sensor.

In some embodiments, input layers 1204 may be trained to emphasize characteristics of an RF signal present in input RF radiation data. For example, such characteristics may include a center frequency, operating frequency band, power level, bandwidth, modulation type, pulse rate, and/or SNR of the RF signal, an extent to which the RF signal matches another RF signal, an extent to which the RF signal is analog and/or digital, and/or a type and/or location of an RF source that transmitted the RF signal. For instance, input layers 1204 may be trained using closed-loop training with another (e.g., downstream) model, at the output of which characteristics of input RF radiation data are labeled. As one example, input layers 1204 may be inverted and attached at the output of model 1200 so as to reconstruct the input RF radiation data for labeled training against the RF radiation data as it was received, which may be effective to train input layers 1204 to preserve distinguishing characteristics of the RF radiation data even if the resulting reconstructed RF radiation data is not itself useful for downstream processing. As shown in FIG. 12A, input layers 1204 include four convolutional layers Conv_1, Conv_2, Conv_3, Conv_4, each followed by a respective max pooling (MP) layer MP1, MP2, MP3, and MP4. Alternative or additional layers may be included, depending on the implementation, such as the dimensionality of the input data and/or the desired level of model accuracy weighed against model complexity (e.g., and associated need for computing resources).

In some embodiments, transformation layers 1206 may be configured to encode characteristics of an RF signal emphasized by input layers 1404 into content of a multidimensional encoding. As shown in FIG. 12B, transformation layers 1206 include feed forward (FF) layers FF1 and FF2 and a self-attention (SA) layer. In some embodiments, transformation layers 1406 may be trained to weight portions of input RF radiation data based on the extent to which they contribute to emphasized characteristics of an RF signal therein (e.g., less weight for portions that contribute less). For example, the illustrated SA layer may be trained to filter out such content using closed-loop training with another (e.g., downstream) model at the output of which characteristics of input RF radiation data are labeled and compared.

In some embodiments, model 1200 may further include analysis components 1208 (FIG. 12B). For example, analysis components 1208 may be configured to provide statistical analysis of outputs from output layer (OL) of model 1200. For instance, in FIG. 12B, analysis components 1208 include components configured to output a confidence metric (e.g., indicating a probability) that an RF signal within digital samples 1202 is analog and FM, analog and AM, and digital. In some embodiments, analysis components 1208 may be configured to determine a confidence metric of a characteristic using content in dimensions of a multidimensional encoding output from OL of model 1200. For example, input layers 1204 and/or transformation layers 1206 of model 1200 may be trained to emphasize characteristics corresponding to probabilities determined using analysis components 1208, such as by comparing labeled probability data against outputs of analysis components 1208. For instance, analysis components 1208 may compare some or all dimensions of a multidimensional encoding to respective thresholds to determine probabilities for various characteristics, whether individually or using a same operation. Alternatively or additionally, analysis components 1208 may be configured to perform logistic regression and/or classification on a multidimensional encoding output from model 1200.

Alternative or additional examples of analysis components 1208 may be configured to output a confidence metric that an RF signal within digital samples 1202 is a chirp, frequency-shift keyed (FSK), amplitude shift keyed (ASK), phase shift keyed (PSK), chirp spread spectrum (CSS), and/or part of a particular constellation. In some embodiments, analysis components 1208 may be replaceable (e.g., in whole or in part) with alternative analysis components configured to output other probabilities without changing layers of mode 1200. For example, model 1200 may be trained with some or all analysis components 1208 such that, analysis components 1208 with which model 1200 was trained may be added or removed without impacting functionality of other parts of model 1200. In some embodiments, analysis components 1208 may be added with which model 1200 was not trained, such as a component that compares an output multidimensional encoding with another multidimensional encoding (e.g., by performing a multidimensional distance determination). For instance, some analysis components 1208 may benefit from training of model 1200 on labels other than the output to be obtained from those components.

### VII. Listing of Non-limiting Implementation Examples

According to a first example aspect, a method of detecting an RF anomaly in an RF system comprises: obtaining, by one or more processors operatively coupled to a memory, a representation of an RF signal, the representation generated using digital samples of RF radiation received by an RF sensor in an operating environment, the RF radiation including the RF signal; and determining, by the one or more processors, using the representation, whether the RF signal is anomalous compared to a baseline of representations of RF signals received in the operating environment.

In some embodiments, the representation comprises a compressed multidimensional representation generated by a trained model in response to inputting the digital samples into the trained model.

In some embodiments, the method further comprises displaying, in a user interface: an indication that the RF signal is anomalous; and one or more actions for user selection in response to the indication.

According to a second example aspect, a method of providing for user control of RF anomaly detection comprises: displaying, in a user interface, by one or more processors operatively coupled to a memory: characteristics of one or more RF signals detected by one or more RF sensors in an operating environment and determined to be anomalous compared to a baseline of representations of RF signals received in the operating environment; and one or more actions for user selection in response to the characteristics.

In some embodiments, the one or more actions are selected from a group consisting of: jamming an RF signal of the one or more RF signals; instructing the one or more RF sensors to report reception of the RF signal; setting an alert to a companion device upon reporting of the RF signal; associating the RF signal with a group of RF signals; ignoring the RF signal; and automatically ignoring reports of RF signals determined to be similar to the RF signal.

According to a third example aspect, a method of detecting an RF anomaly in an RF system comprises, by at least one processor: obtaining a multidimensional encoding of characteristics of an RF signal, the multidimensional encoding generated using digital samples of RF radiation received by an RF sensor in an operating environment; and determining, based on the multidimensional encoding, that the RF signal is anomalous compared to a baseline of multidimensional encodings of characteristics of RF radiation received in the operating environment.

In some embodiments, the multidimensional encoding is output by a model trained to provide the multidimensional encoding in response to inputting the digital samples.

In some embodiments, the method further comprises, by the RF sensor, executing the model, inputting the digital samples to the model, and providing the multidimensional encoding as an output from the model.

In some embodiments, the method further comprises, by the at least one processor, receiving the multidimensional encoding from the RF sensor over a communication network.

In some embodiments, the multidimensional encoding consumes less memory than a subset of the digital samples that indicate the RF signal.

In some embodiments, determining that the RF signal is anomalous comprises determining that a multidimensional distance between the multidimensional encoding of characteristics of the RF signal and the baseline of multidimensional encodings exceeds a predetermined multidimensional distance.

In some embodiments, wherein determining the multidimensional distance is between the multidimensional encoding and a multidimensional space of the baseline.

In some embodiments, the RF signal is a deviated version of a baseline RF signal in the RF radiation included in the baseline that has deviated in operating condition by more than a predetermined extent.

In some embodiments, the RF signal was transmitted by an RF source that has not transmitted RF radiation included in the baseline.

In some embodiments, the RF signal was transmitted by an RF source that has transmitted RF radiation included in the baseline.

In some embodiments, the method further comprises associating the RF signal with at least one other anomalous RF signal.

In some embodiments, the multidimensional encoding of characteristics of the RF signal is within a predetermined multidimensional distance from at least one multidimensional encoding of characteristics of the at least one other anomalous RF signal.

In some embodiments, the at least one other anomalous signal comprises a grouping of anomalous RF signals of which multidimensional encodings of characteristics thereof are within the predetermined multidimensional distance from one another, and the predetermined multidimensional distance is from the grouping of multidimensional encodings of characteristics of the grouping of anomalous RF signals.

In some embodiments, the grouping of anomalous RF signals are further within a predetermined difference in frequency from one another.

In some embodiments, associating the RF signal with the at least one other anomalous RF signal is in response to an instruction received from a user identifying the at least one other anomalous RF signal.

In some embodiments, associating the RF signal with the at least one other anomalous RF signal is in response to an instruction received from a user that sets the predetermined multidimensional distance.

In some embodiments, the method further comprises disassociating the RF signal from the at least one another anomalous RF signal in response to an instruction received from a user.

In some embodiments, the method further comprises, in response to an instruction received from a user, performing at least one action selected from a group consisting of: ignoring the multidimensional encoding; adding the multidimensional encoding to a grouping of associated multidimensional encodings; creating a new grouping of associated multidimensional encodings including the multidimensional encoding; adding the multidimensional encoding to the baseline; obtaining the digital samples of the RF radiation; instructing an RF sensor of the RF system to provide digital samples of RF radiation associated with the RF signal; and communicating an alert over a communication network indicating the RF signal determined to be anomalous.

In some embodiments, obtaining the multidimensional encoding of characteristics of the RF signal comprises: identifying, within RF data of a first frequency range over which the RF sensor scans for RF radiation, a second frequency range contained within the first frequency range and indicated as including RF radiation; detecting, within RF radiation data of the RF radiation in the second frequency range, the RF signal; and generating the multidimensional encoding of characteristics of the RF signal using digital samples of the RF radiation.

In some embodiments. the baseline of multidimensional encodings of characteristics comprises a baseline multidimensional space that is generated based on a plurality of multidimensional encodings of characteristics of baseline RF radiation received from the operating environment.

In some embodiments, the baseline multidimensional space represents the plurality of multidimensional encodings in aggregate.

In some embodiments, the baseline multidimensional space comprises a Gaussian mixture of the plurality of multidimensional encodings.

In some embodiments, the baseline RF radiation is received at predetermined times and in a predetermined frequency range.

In some embodiments, the baseline RF radiation is received at overlapping times and in a plurality of different frequency ranges.

In some embodiments, the baseline multidimensional space comprises a projected estimation of RF radiation at times other than the overlapping times, the projected estimation based on the baseline RF radiation received at the overlapping times.

In some embodiments, determining that the RF signal is anomalous compared to the baseline comprises inputting, at different respective times, the baseline of multidimensional encodings and the multidimensional encoding of characteristics of the RF signal into a model and determining that the RF signal is anomalous based on an output from the model.

In some embodiments, the model is selected from a group consisting of: a sphericity model; an autocorrelation model; and a quadratic time-dependence model.

According to a fourth example aspect, an RF system configured to detect an RF anomaly comprises at least one processor configured to: obtain a multidimensional encoding of characteristics of an RF signal, the multidimensional encoding generated using digital samples of RF radiation received by an RF sensor in an operating environment; and determine, based on the multidimensional encoding, that the RF signal is anomalous compared to a baseline of multidimensional encodings of characteristics of RF radiation received in the operating environment.

In some embodiments, the multidimensional encoding is output by a model trained to provide the multidimensional encoding in response to inputting the digital samples.

In some embodiments, the RF system further comprises the RF sensor, wherein the RF sensor is configured to execute the model, input the digital samples to the model, and provide the multidimensional encoding as an output from the model.

In some embodiments, the at least one processor is configured to receive the multidimensional encoding from the RF sensor over a communication network.

In some embodiments, the multidimensional encoding consumes less memory than a subset of the digital samples that indicate the RF signal.

In some embodiments, the at least one processor is configured to determine that the RF signal is anomalous at least in part by determining that a multidimensional distance between the multidimensional encoding of characteristics of the RF signal and the baseline of multidimensional encodings exceeds a predetermined multidimensional distance.

In some embodiments, the RF signal is a deviated version of a baseline RF signal in the RF radiation included in the baseline that has deviated in operating condition by more than a predetermined extent.

In some embodiments, the at least one processor is further configured to, in response to an instruction received from a user, perform at least one action selected from a group consisting of: ignoring the multidimensional encoding; adding the multidimensional encoding to a grouping of associated multidimensional encodings; creating a new grouping of associated multidimensional encodings including the multidimensional encoding; adding the multidimensional encoding to the baseline; obtaining the digital samples of the RF radiation; instructing an RF sensor of the RF system to provide digital samples of RF radiation associated with the RF signal; and communicating an alert over a communication network indicating the RF signal determined to be anomalous.

In some embodiments, he at least one processor is configured to obtain the multidimensional encoding of characteristics of the RF signal at least in part by: identifying, within RF data of a first frequency range over which the RF sensor scans for RF radiation, a second frequency range contained within the first frequency range and indicated as including RF radiation; detecting, within RF radiation data of the RF radiation in the second frequency range, the RF signal; and generating the multidimensional encoding of characteristics of the RF signal using digital samples of the RF radiation.

In some embodiments, the baseline of multidimensional encodings of characteristics comprises a baseline multidimensional space that is generated based on a plurality of multidimensional encodings of characteristics of baseline RF radiation received from the operating environment.

According to a fifth example aspect, a method of controlling RF anomaly detection in an RF system comprises, by at least one processor: displaying, in a graphical user interface to a user: an indication of an RF signal received by the RF system and determined to be anomalous compared to a baseline; and an option selectable by the user to initiate an action by the RF system associated with the RF signal; and responding to selection of the option by the user by initiating the action by the RF system associated with the RF signal.

In some embodiments, the action is selected from a group consisting of: adding the RF signal to the baseline; ignoring the RF signal; obtaining digital samples of the RF signal; instructing an RF sensor of the RF system to provide digital samples of RF radiation associated with the RF signal; and communicating an alert over a communication network indicating the RF signal determined to be anomalous.

In some embodiments, the action comprises adding a multidimensional encoding of the RF signal to the baseline; and the baseline is further generated based on multidimensional encodings of characteristics of RF radiation received by the RF system.

In some embodiments, the action comprises ignoring the RF signal; and the method further comprises, in response to a further indication that the RF signal has been received by the RF system, omitting display of a further indication of that RF signal in the graphical user interface.

In some embodiments, the action comprises ignoring the RF signal; the method further comprises ignoring a second RF signal that is determined to be anomalous; and a first multidimensional encoding of the RF signal is within a predetermined multidimensional distance from a second multidimensional encoding of the second RF signal.

In some embodiments, the action comprises obtaining digital samples of the RF signal; and the method further comprises storing the digital samples of the RF signal in memory of the RF system.

In some embodiments, the action comprises instructing the RF sensor to provide digital samples of RF radiation in a frequency range of the RF signal.

In some embodiments, the RF signal was received by a first RF sensor of the RF system, and instructing the RF sensor to provide the digital samples of the RF radiation comprises instructing a second RF sensor of the RF system.

In some embodiments, the action comprises communicating the alert; and the method further comprises communicating the alert in response to a further indication that the RF signal was received by the RF system.

In some embodiments, the method further comprises generating, based on digital samples of RF radiation received by an RF sensor of the RF system and including the RF signal, a multidimensional encoding of the RF signal; and determining that the RF signal is anomalous by comparing the multidimensional encoding to the baseline, the baseline being generated based on multidimensional encodings of RF radiation received by the RF system.

According to a sixth example aspect, a method of detecting an RF anomaly in an RF system comprises, by at least one processor: obtaining RF data of a first frequency range over which an RF sensor of the RF system scans for RF radiation; identifying a subset of the RF data in which to detect RF anomalies; and determining a presence of the RF anomaly corresponding to the subset of the RF data by comparing a representation of RF radiation corresponding to the subset to a baseline of RF radiation received by the RF system.

In some embodiments, obtaining the RF data comprises generating the RF data by the RF sensor based on digital samples of RF radiation in the first frequency range received by the RF sensor and portions of the first frequency range in which no RF radiation was received by the RF sensor.

In some embodiments, the subset of the RF data comprises RF radiation in a second frequency range contained within the first frequency range.

In some embodiments, identifying the subset of the RF data uses less computing power per unit of frequency over the first frequency range than determining the presence of the RF anomaly uses over the second frequency range.

In some embodiments, identifying the subset of the RF data comprises identifying the second frequency range as including RF radiation.

In some embodiments, identifying the second frequency range as including RF radiation comprises determining that RF radiation data of RF radiation in the second frequency range has at least a predetermined power level.

In some embodiments, determining the presence of the RF anomaly is performed using RF radiation data obtained from the subset of the RF data.

In some embodiments, the method further comprises instructing an RF sensor of the system to provide RF radiation data in the second frequency range, wherein determining the presence of the RF anomaly is performed using the RF radiation data in the second frequency range.

In some embodiments, determining the presence of the RF anomaly comprises generating a multidimensional encoding of characteristics of RF radiation corresponding to the subset of the RF data and comparing the multidimensional encoding to a baseline of multidimensional encodings of RF radiation received by the RF system.

According to a seventh example aspect, an RF system configured to detect an RF anomaly comprises at least one processor configured to perform the method of any one of the embodiments of the sixth example aspect.

Having thus described several aspects and embodiments of the technology set forth in the disclosure, it is to be appreciated that various alterations, modifications, and improvements will readily occur to those skilled in the art. Such alterations, modifications, and improvements are intended to be within the spirit and scope of the technology described herein. For example, those of ordinary skill in the art will readily envision a variety of other means and/or structures for performing the function and/or obtaining the results and/or one or more of the advantages described herein, and each of such variations and/or modifications is deemed to be within the scope of the embodiments described herein. Those skilled in the art will recognize, or be able to ascertain using no more than routine experimentation, many equivalents to the specific embodiments described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The above-described embodiments may be implemented in any of numerous ways. One or more aspects and embodiments of the present disclosure involving the performance of processes or methods may utilize program instructions executable by a device (e.g., a computer, a processor, or other device) to perform, or control performance of, the processes or methods. In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various embodiments described above. The computer readable medium or media may be transportable, such that the program or programs stored thereon may be loaded onto one or more different computers or other processors to implement various ones of the aspects described above. In some embodiments, computer readable media may be non-transitory media.

The terms “program” or “software” are used herein in a generic sense to refer to any type of computer code or set of computer-executable instructions that may be employed to program a computer or other processor to implement various aspects as described above. Additionally, it should be appreciated that according to one aspect, one or more computer programs that when executed perform methods of the present disclosure need not reside on a single computer or processor, but may be distributed in a modular fashion among a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

When implemented in software, the software code may be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a Personal Digital Assistant (PDA), a smartphone or any other suitable portable or fixed electronic device.

Also, a computer may have one or more input and output devices. These devices may be used, among other things, to present a user interface. Examples of output devices that may be used to provide a user interface include printers or display screens for visual presentation of output and speakers or other sound generating devices for audible presentation of output. Examples of input devices that may be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The terms “approximately” and “about” may be used to mean within ±20% of a target value in some embodiments, within ±10% of a target value in some embodiments, within ±5% of a target value in some embodiments, within ±2% of a target value in some embodiments. The terms “approximately” and “about” may include the target value.

1. A method of detecting an RF anomaly in an RF system, the method comprising, by at least one processor:
obtaining a multidimensional encoding of characteristics of an RF signal, the multidimensional encoding generated using digital samples of RF radiation received by an RF sensor in an operating environment; and
determining, based on the multidimensional encoding, that the RF signal is anomalous compared to a baseline of multidimensional encodings of characteristics of RF radiation received in the operating environment.

2. The method of claim 1, wherein the multidimensional encoding is output by a model trained to provide the multidimensional encoding in response to inputting the digital samples.

3. The method of claim 2, further comprising, by the RF sensor, executing the model, inputting the digital samples to the model, and providing the multidimensional encoding as an output from the model.

4. The method of claim 3, further comprising, by the at least one processor, receiving the multidimensional encoding from the RF sensor over a communication network.

5. The method of claim 1, wherein the multidimensional encoding consumes less memory than a subset of the digital samples that indicate the RF signal.

6. The method of claim 1, wherein determining that the RF signal is anomalous comprises determining that a multidimensional distance between the multidimensional encoding of characteristics of the RF signal and the baseline of multidimensional encodings exceeds a predetermined multidimensional distance.

7. The method of claim 1, wherein the RF signal is a deviated version of a baseline RF signal in the RF radiation included in the baseline that has deviated in operating condition by more than a predetermined extent.

8. The method of claim 1, further comprising, in response to an instruction received from a user, performing at least one action selected from a group consisting of:
ignoring the multidimensional encoding;
adding the multidimensional encoding to a grouping of associated multidimensional encodings;
creating a new grouping of associated multidimensional encodings including the multidimensional encoding;
adding the multidimensional encoding to the baseline;
obtaining the digital samples of the RF radiation;
instructing an RF sensor of the RF system to provide digital samples of RF radiation associated with the RF signal; and
communicating an alert over a communication network indicating the RF signal determined to be anomalous.

9. The method of claim 1, wherein obtaining the multidimensional encoding of characteristics of the RF signal comprises:
identifying, within RF data of a first frequency range over which the RF sensor scans for RF radiation, a second frequency range contained within the first frequency range and indicated as including RF radiation;
detecting, within RF radiation data of the RF radiation in the second frequency range, the RF signal; and
generating the multidimensional encoding of characteristics of the RF signal using digital samples of the RF radiation.

10. The method of claim 1, wherein the baseline of multidimensional encodings of characteristics comprises a baseline multidimensional space that is generated based on a plurality of multidimensional encodings of characteristics of baseline RF radiation received from the operating environment.

11. An RF system configured to detect an RF anomaly, the RF system comprising at least one processor configured to:
obtain a multidimensional encoding of characteristics of an RF signal, the multidimensional encoding generated using digital samples of RF radiation received by an RF sensor in an operating environment; and
determine, based on the multidimensional encoding, that the RF signal is anomalous compared to a baseline of multidimensional encodings of characteristics of RF radiation received in the operating environment.

12. The RF system of claim 11, wherein the multidimensional encoding is output by a model trained to provide the multidimensional encoding in response to inputting the digital samples.

13. The RF system of claim 12, further comprising the RF sensor, wherein the RF sensor is configured to execute the model, input the digital samples to the model, and provide the multidimensional encoding as an output from the model.

14. The RF system of claim 13, wherein the at least one processor is configured to receive the multidimensional encoding from the RF sensor over a communication network.

15. The RF system of claim 11, wherein the multidimensional encoding consumes less memory than a subset of the digital samples that indicate the RF signal.

16. The RF system of claim 11, wherein the at least one processor is configured to determine that the RF signal is anomalous at least in part by determining that a multidimensional distance between the multidimensional encoding of characteristics of the RF signal and the baseline of multidimensional encodings exceeds a predetermined multidimensional distance.

17. The RF system of claim 11, wherein the RF signal is a deviated version of a baseline RF signal in the RF radiation included in the baseline that has deviated in operating condition by more than a predetermined extent.

18. The RF system of claim 11, wherein the at least one processor is further configured to, in response to an instruction received from a user, perform at least one action selected from a group consisting of:
ignoring the multidimensional encoding;
adding the multidimensional encoding to a grouping of associated multidimensional encodings;
creating a new grouping of associated multidimensional encodings including the multidimensional encoding;
adding the multidimensional encoding to the baseline;
obtaining the digital samples of the RF radiation;
instructing an RF sensor of the RF system to provide digital samples of RF radiation associated with the RF signal; and
communicating an alert over a communication network indicating the RF signal determined to be anomalous.

19. The RF system of claim 11, wherein the at least one processor is configured to obtain the multidimensional encoding of characteristics of the RF signal at least in part by:
identifying, within RF data of a first frequency range over which the RF sensor scans for RF radiation, a second frequency range contained within the first frequency range and indicated as including RF radiation;
detecting, within RF radiation data of the RF radiation in the second frequency range, the RF signal; and
generating the multidimensional encoding of characteristics of the RF signal using digital samples of the RF radiation.

20. The RF system of claim 11, wherein the baseline of multidimensional encodings of characteristics comprises a baseline multidimensional space that is generated based on a plurality of multidimensional encodings of characteristics of baseline RF radiation received from the operating environment.
